(19) United States
(12) Patent Application Publication
(10) Pub. No.: US 2026/0275571 A1
(43) Pub. Date: Sep. 17, 2026

(54) METAL HALIDE PEROVSKITE-CHALCOGENIDE EPITAXIAL HETEROSTRUCTURE NANOCRYSTAL AND METHOD OF PREPARING SAME

(71) Applicant: The Industry & Academic Cooperation in Chungnam National University (IAC), Daejeon (KR)

(72) Inventors: Jihoon CHOI, Daejeon (KR); Artavazd Kirakosyan, Daejeon (KR)

(73) Assignee: The Industry & Academic Cooperation in Chungnam National University (IAC), Daejeon (KR)

(21) Appl. No.: 19/320,197

(22) Filed: Sep. 5, 2025

(30) Foreign Application Priority Data
Mar. 17, 2025 (KR) 10-2025-0033788

(51) Int. Cl. C30B 29/12; C09K 11/88; C30B 7/00; C30B 7/14; C30B 29/48; H10K 30/30; H10K 71/00; H10K 71/12

(52) U.S. Cl. CPC C30B 29/12; C09K 11/881; C30B 7/005; C30B 7/14; C30B 29/48; H10K 30/30; H10K 71/12; H10K 71/311

(57) ABSTRACT

Proposed are a metal halide perovskite (MHP)-chalcogenide epitaxial heterostructure nanocrystal (NC) characterized by including a first domain of an MHP satisfying CsPbX₃ (where X is a halide) and a second domain of a PbTe chalcogenide, the second domain grown on one surface of the first domain, wherein the first and second domains form an epitaxial junction while achieving lattice matching, and a method of preparing the same.

### CROSS REFERENCE TO RELATED APPLICATION

The present application claims priority to Korean Patent Application No. 10-2025-0033788, filed on Mar. 17, 2025, the entire contents of which is incorporated herein by reference.

### BACKGROUND

### 1. Technical Field

The present disclosure relates to a metal halide perovskite (MHP)-chalcogenide epitaxial heterostructure nanocrystal (NC) and a method of preparing the same.

### 2. Description of the Related Art

MHP NCs have emerged as promising semiconductor materials for a wide range of optoelectronic applications, including photovoltaics, light-emitting diodes (LEDS), and photodetectors. Progress has been made in synthesis technologies of MHP NCs, which enables precise control over composition, dimension, and morphology, thereby enhancing optical properties such as band-gap energy, emission efficiency, charge carrier diffusion, and stability. In particular, increasing the mobility and lifetime of charge carriers is emerging as a major research project for the development of high-efficiency photoelectric conversion devices.

Recently, perovskite NC-based heterostructures have garnered attention as a novel approach capable of improving photovoltaic and photocatalytic performance by modulating charge carrier dynamics. The performance of heterostructures is determined through energy band alignment at heterojunction interfaces. In particular, epitaxial heterojunctions play a crucial role in efficiently confining and transporting charge carriers across domains by reducing disruptions in the periodic potential of the crystalline lattice. Disruptions in the periodic potential can affect momentum conservation by causing charge carrier scattering or energy loss, so epitaxial junctions capable of minimizing such disruptions are essential.

Various perovskite heterostructures (for example, perovskite-chalcogenide, perovskite-transition metal dichalcogenide, perovskite-metal, and perovskite-oxide) have been studied to date. However, in most heterojunctions, there have been problems where secondary phases are randomly deposited on the surface of perovskite NCs, preventing the establishment of an epitaxial relationship. Well-established perovskite-chalcogenide epitaxial heterostructures can offer enhanced charge transport properties and reduced charge recombination rates. However, due to the ionic-covalent bonding properties and crystallographic differences (for example, differences in metal ion coordination structures) between perovskites and chalcogenides, forming high-quality epitaxial junctions still remains a challenging task.

Typically, strategies for forming NC-based epitaxial heterostructures involve inducing selective nucleation of secondary phases on specific facets of the host crystal and promoting growth through lattice matching between the individual crystalline components at the interface. Attempts have been made in existing studies to induce the growth of chalcogenide phases on specific facets of perovskite NCs, but problems where lattice alignment is incomplete or defects are formed at the interface, leading to inefficient charge transport, have occurred. Furthermore, although lead chalcohalide (Pb₄S₃Br₂ and Pb₄S₃Cl₂)— or lead-chalcogenide (PbBi₂S₄)-based heterostructures have been developed in some studies, there are limitations as the insufficient structural continuity between perovskites and chalcogenides leads to increased charge recombination rates and reduced photoconversion efficiency.

In this regard, in Non-Patent Document 1, epitaxial heterostructures of perovskite-lead chalcohalide NCs, such as CsPbX₃—Pb₄S₃Br₂ (where X is Cl, Br, or I) and CsPbCl₃-Pb₄S₃Cl₂, have been reported. In these structures, lead chalcogenide domains were preferentially grown on the (101) facets of orthorhombic CsPbBr₃ NC cubes, resulting in minimal lattice mismatch at the interface. Furthermore, Pb₄S₄X₂ was found to share a Pb²⁺ sublattice similar to that of CsPbX₃ perovskite and derivatives thereof, ensuring structural continuity across the perovskite and chalcohalide interface.

In Non-Patent Document 2, perovskite-chalcogenide heterostructures composed of CsPbBr₃ NCs and PbBi₂S₄ nanorods in the presence of the common Pb(II) sublattice structure have been published. However, earlier studies primarily focused on chalcohalides and chalcogenides containing both lead and sulfur, due to the comparable crystalline characteristics and lattice spacing between lead sulfide (a_{Pb8}=5.936 Å) and orthorhombic CsPbBr₃ NCs (d=0.58 nm for {110} and {002} facets).

Lead selenide and telluride (Te), which contain the common Pb²⁺ sublattice similar to CsPbX₃ perovskite, are promising candidates for optoelectronic applications. Although the lattice parameters thereof (a_{PbSe}=6.12 Å, a_{PbTe}=6.46 Å) are larger than those of CsPbBr₃ NCs, precise control over facets with close lattice matching can be achieved by using CsPbBr₃ nanoclusters as precursors. This approach promotes the structural evolution and transformation of intermediate CsPbBr₃ polyhedrons into NCs with various facets. For example, in Non-Patent Document 3, the formation of CsPbBr₃ hexapods with four {110} and two {002} facets through selective dissolution in a 26-faceted rhombicuboctahedral CsPbBr₃ NCs has been reported.

### DOCUMENTS OF RELATED ART

### Non-Patent Documents

(Non-Patent Document 1) Journal of the American Chemical Society, 2021, 143, 1435-1446; Halide Perovskite-Lead Chalcohalide Nanocrystal Heterostructures.
(Non-Patent Document 2) Chemistry of Materials, 2024, 36, 3803-3811; Perovskite-chalcogenide epitaxial heterostructures: Possibility of multiple axial orientations of CsPbBr₃ nanocrystals on PbBi₂S₄ nanorods.
(Non-Patent Document 3) Journal of the American Chemical Society, 2019, 141, 16160-16168; Arm Growth and Facet Modulation in Perovskite Nanocrystals.

### SUMMARY

In order to solve the problems described above, the present disclosure aims to provide an MHP-chalcogenide epitaxial heterostructure NC, in which a first domain of an MHP and a second domain of a PbTe chalcogenide, the second domain grown on one surface of the first domain, form an epitaxial junction while achieving lattice matching, and a method of preparing the same.

However, the above objectives are exemplary, and the technical ideas of the present disclosure are not limited thereto.

A first embodiment of the present disclosure for achieving the objectives mentioned above relates to an MHP-chalcogenide epitaxial heterostructure NC characterized by including: a first domain of an MHP satisfying CsPbX₃ (where X is a halide); and a second domain of a PbTe chalcogenide, the second domain grown on one surface of the first domain, wherein the first and second domains form an epitaxial junction while achieving lattice matching.

The first embodiment may be characterized in that a (112) plane of the first domain and a (111) plane of the second domain form the epitaxial junction while achieving lattice matching.

The first embodiment may be characterized in that the first and second domains share a common Pb²⁺ sublattice and exhibit structural continuity.

The first embodiment may be characterized in that the first domain has an average size in a range of 5 to 100 nm and has a cubic or polyhedral morphology.

The first embodiment may be characterized in that the second domain has an average size in a range of 1 to 20 nm and has a spherical or polyhedral morphology.

The first embodiment may be characterized in that the MHP-chalcogenide epitaxial heterostructure NC has an average photoluminescence (PL) decay time (τ_{avg}) of 5 ns or less at a temperature of 80 K.

The first embodiment may be characterized in that the MHP-chalcogenide epitaxial heterostructure NC has a PL quantum yield (PLQY) of 5% or less at a temperature of 80 K.

Additionally, a second embodiment of the present disclosure relates to a method of preparing an MHP-chalcogenide epitaxial heterostructure NC, the method characterized by including the following steps: a) preparing a first domain precursor of an MHP satisfying CsPbX₃ (where X is a halide) and a second domain precursor of a PbTe chalcogenide, respectively; and b) growing a second domain on one surface of a first domain by reacting the first domain precursor with the second domain precursor, wherein the first and second domains form an epitaxial junction while achieving lattice matching.

The second embodiment may be characterized in that the first domain precursor is prepared by adding and reacting cesium oleate to and with a first reaction solution including PbX₂ (where X is a halide), a fatty acid, and a fatty amine.

The second embodiment may be characterized in that the second domain precursor of the PbTe chalcogenide is prepared by reacting a second reaction solution including Te powder and trioctylphosphine (TOP).

The second embodiment may be characterized in that Step b) is performed by reacting a third reaction solution including the first domain precursor, the second domain precursor, lead oleate, and 1-dodecanethiol (DDT).

Furthermore, a third embodiment of the present disclosure relates to an optoelectronic device including the aforementioned MHP-chalcogenide epitaxial heterostructure NC.

An MHP-chalcogenide epitaxial heterostructure NC, according to the present disclosure, provides a novel nanostructure exhibiting excellent charge transport properties and a broadened light absorption range. In particular, by forming an epitaxial junction through lattice matching between a first domain (CsPbX₃, where X is a halide) and a second domain (PbTe), charge recombination can be effectively suppressed while maintaining structural continuity between the two domains. This allows existing problems with random junctions to be solved and enables high photoelectric conversion efficiency to be maintained.

Additionally, in the present disclosure, the (112) plane of the first domain and the (111) plane of the second domain form an epitaxial junction while achieving lattice matching, so possible defects at the interface can be minimized, which leads to enhanced charge mobility and, in particular, can further facilitate charge separation and extraction processes in optoelectronic devices. Furthermore, the first and second domains can share a common Pb²⁺ sublattice and exhibit structural continuity. As described above, charge carriers are allowed to move across the interface without scattering by sharing the common Pb²⁺ sublattice between the perovskite and the chalcogenide, providing high charge mobility and enabling the photoelectric conversion efficiency to be maximized. Moreover, by increasing structural stability and enhancing crystallographic stability between the two materials, higher crystallinity can be maintained.

### BRIEF DESCRIPTION OF THE DRAWINGS

FIG. 1 is a schematic diagram illustrating the formation process of CsPbBr₃—PbTe heterostructure NCs;

FIG. 2 shows a transmission electron microscopy (TEM) image of CsPbBr₃—PbTe heterostructure NCs;

FIGS. 3A and 3B show the size distributions of CsPbBr₃ NCs and PbTe NCs, respectively, the results of which are obtained through statistical measurement performed on 100 NCs;

FIGS. 4A and 4B show high-resolution TEM (HRTEM) images of a single CsPbBr₃—PbTe heterostructure NC, and FIGS. 4C and 4D show selected area fast Fourier transform (FFT) patterns for Domain 1 (CsPbBr₃) and Domain 2 (PbTe), respectively;

FIG. 5 shows a TEM image of a CsPbBr₃—PbTe heterostructure NC annealed for 5 min, indicating that the PbTe domain has a spherical morphology;

FIG. 6 shows an atomic model illustrating the characteristics of a CsPbBr₃—PbTe crystallographic heterostructure NC, highlighting interfacial orientation and specific facets;

FIG. 7 shows X-ray diffraction (XRD) patterns measured for pristine CsPbBr₃ NCS (top, black), CsPbBr₃—PbTe heterostructure NCs (middle, red), and PbTe NCs (bottom, blue) in various diffraction angle ranges;

FIGS. 8A, 8B, 8C, and 8D show a TEM image of pristine CsPbBr₃ NCs, the size distribution thereof determined through statistical analysis performed on 100 NCs, a magnified TEM image, and an FFT pattern, respectively;

FIGS. 9A, 9B, 9C, 9D, and 9E show the appearance of a colloidal solution, a TEM image of PbTe heterostructure NCs, a magnified TEM image, an FFT pattern, and analysis results of interplanar distances of (001) planes, respectively;

FIG. 10 shows a TEM image of byproducts resulting from side reactions, such as PbBr(OH), formed in an NC solution due to air exposure;

FIGS. 11A and 11B show crystal structure models of an orthorhombic CsPbBr₃ phase and a cubic PbTe phase, respectively, and FIGS. 11C and 11D show atomic models of Pb sublattices for CsPbBr₃ {112} planes and PbTe {111} planes, respectively;

FIG. 12 shows comparative data on d-spacings of Pb sublattices for several crystalline planes commonly observed in CsPbBr₃ and PbTe NCs;

FIG. 13 shows an HRTEM image of a heterojunction between CsPbBr₃ and PbTe NCs, and an atomic model of the corresponding interface;

FIG. 14 shows an image of spatially resolved scanning transmission electron microscopy-electron energy loss spectroscopy (STEM-EELS) intensity for a single CsPbBr₃—PbTe heterostructure NC;

FIG. 15 shows a STEM-high-angle annular dark field (HAADF) image of the single CsPbBr₃—PbTe heterostructure NC of FIG. 14, and five STEM-EELS elemental maps showing Cs-M_{4,5}, Pb-M_{4,5}, Br-L_{2,3}, Te-M_{4,5}, and O-K edge signals;

FIG. 16 shows a line profile along the dashed line marked in FIG. 14, depicting the distribution of Cs, Pb, Br, Te, and O signals;

FIG. 17 shows comparative data on EELS spectra of pristine PbTe NCs (top) and CsPbBr₃—PbTe heterostructure NCs (bottom);

FIGS. 18A, 18B, and 18C show X-ray photoelectron spectroscopy (XPS) spectra of Pb 4f, Te 3d, and O 1s for CsPbBr₃—PbTe heterostructure NCs (top panels) and pristine PbTe NCs (bottom panels), respectively;

FIG. 19 is a photograph of an aged TOP-Te solution, showing TeO₂ precipitates formed after long-term air exposure;

FIGS. 20A and 20B show XPS spectra of C 1s for pristine CsPbBr₃ NCs and CsPbBr₃—PbTe heterostructure NCs, respectively;

FIGS. 21A and 21B show low- and high-magnification TEM images of CsPbBr₃—PbTe heterostructure NCs obtained in the absence of Pb-oleate during the synthesis process, respectively;

FIG. 22 shows TEM images of CsPbBr₃—PbTe heterostructure NCs at different magnifications, obtained in the absence of DDT during the synthesis process;

FIGS. 23A and 23B show a TEM image and data on the size distribution of CsPbBr₃ NCs obtained using DDT and Pb-oleate during the synthesis process, respectively, and FIGS. 23C and 23D show a high-magnification TEM image of a typical NC and the corresponding FFT image, respectively;

FIGS. 24A and 24B show a TEM image and data on the size distribution of CsPbBr₃ NCs obtained using only Pb-oleate during the synthesis process, respectively, and FIGS. 24C and 24D show a high-magnification TEM image of a typical NC and the corresponding FFT image, respectively;

FIG. 25 shows ultraviolet-visible (UV-Vis) absorbance spectra of pristine CsPbBr₃ NCs, PbTe NCs, and CsPbBr₃—PbTe heterostructure NCs;

FIG. 26A shows a Tauc plot in which UV-Vis-near-infrared (UV-Vis-NIR) absorption spectra of pristine PbTe NCs (red), CsPbBr₃—PbTe heterostructure NCs (blue), and pristine CsPbBr₃ NCs (black) are analyzed, and FIG. 26B shows a graph in which the region marked with a line pattern in FIG. 26A is enlarged;

FIG. 27 shows normalized PL spectra of the same samples, where the insets represent photographs of the emission for a CsPbBr₃—PbTe colloidal solution under daylight and UV (λ=365 nm) illumination;

FIG. 28 is a schematic diagram illustrating an energy band structure of CsPbBr₃—PbTe heterostructure NCs and the resulting charge recombination process;

FIGS. 29A-29C show ultraviolet photoelectron spectroscopy (UPS) measurement results of CsPbBr₃—PbTe heterostructure NCs, pristine CsPbBr₃ NCs, and PbTe NCs, where FIGS. 29A, 29B, and 29C show the entire spectra, enlarged spectra of secondary electron cut-off regions for each sample, and enlarged spectra of the valence-band regions;

FIG. 30 is an energy band diagram of pristine CsPbBr₃ NCs, PbTe NCs, and the resulting CsPbBr₃—PbTe heterostructure NCs formed;

FIG. 31 shows temperature-dependent time-resolved PL (TRPL) spectra of pristine CsPbBr₃ NCs N and CsPbBr₃—PbTe heterostructure NCs;

FIG. 32 shows data on average PL decay time of pristine CsPbBr₃ NCs and CsPbBr₃—PbTe heterostructure NCs in a temperature range of 80 to 300 K;

FIG. 33 shows comparative data on the fractions of PL decay components (τ₁, τ₂, and τ₃) at a temperature of 300 K;

FIG. 34 shows data on a temperature-dependent PL two-dimensional (2D) pseudo-color plot of CsPbBr₃—PbTe heterostructure NCs measured in a temperature range of 80 to 300 K;

FIG. 35 shows a graph illustrating the temperature dependence of integrated PL intensity, where symbols and lines denote experimental and fitting results, respectively;

FIG. 36 shows a graph illustrating the temperature dependence of full width at half maximum (FWHM) of the emission spectrum, where symbols and lines denote experimental and fitting results, respectively, and the insets represent the longitudinal optical (LO) phonon coupling coefficient (Γ_{LO}) and LO phonon energy (ℏω_{LO});

FIG. 37 shows a cross-sectional SEM image of a CsPbBr₃—PbTe heterostructure NC-based self-powered photodetector device;

FIGS. 38A, 38B, and 38C show photocurrent responses for a CsPbBr₃ thin film, CsPbBr₃ NCs, and CsPbBr₃—PbTe heterostructure NCs, respectively;

FIGS. 39A and 39B show transient photocurrent curves of a photocurrent device for CsPbBr₃ NCs and CsPbBr₃—PbTe heterostructure NCs, respectively; and

FIGS. 40A and 40B show the responsivity and detectivity of a CsPbBr₃ thin film, CsPbBr₃ NCs, and CsPbBr₃—PbTe heterostructure NCs, respectively.

### DETAILED DESCRIPTION

Hereinafter, an MHP-chalcogenide epitaxial heterostructure NC and a method of preparing the same, according to the present disclosure, are to be described in detail. The accompanying drawings are provided as examples to fully convey the idea of the present disclosure to those skilled in the art. Accordingly, the present disclosure is not limited to the accompanying drawings and may be embodied in other forms. Additionally, the accompanying drawings may be exaggerated to clarify the idea of the present disclosure. In this case, technical and scientific terms used herein have the same meaning as commonly understood by those skilled in the art to which the present disclosure pertains, unless otherwise defined. Furthermore, in the following description and accompanying drawings, it is to be noted that descriptions of known functions and configurations that may unnecessarily obscure the gist of the present disclosure are to be omitted.

A first embodiment of the present disclosure relates to an MHP-chalcogenide epitaxial heterostructure NC characterized by including: a first domain of an MHP satisfying CsPbX₃ (where X is a halide); and a second domain of a PbTe chalcogenide, the second domain grown on one surface of the first domain, wherein the first and second domains form an epitaxial junction while achieving lattice matching. Here, the halide may be one or more selected from F, Br, Cl, and I, and is preferably one or more selected from Br and Cl.

As described above, the MHP-chalcogenide epitaxial heterostructure NC, according to the present disclosure, provides a novel nanostructure exhibiting excellent charge transport properties and a broadened light absorption range. In particular, by forming the epitaxial junction through lattice matching between the first domain (CsPbX₃, where X is a halide) and the second domain (PbTe), charge recombination can be effectively suppressed while maintaining structural continuity between the two domains. This allows existing problems with random junctions to be solved and enables high photoelectric conversion efficiency to be maintained.

Additionally, in the present disclosure, the (112) plane of the first domain and the (111) plane of the second domain form the epitaxial junction while achieving lattice matching, so possible defects at the interface can be minimized, which leads to enhanced charge mobility and, in particular, can further facilitate charge separation and extraction processes in optoelectronic devices. Furthermore, the first and second domains can share a common Pb²⁺ sublattice and exhibit structural continuity. As described above, charge carriers are allowed to move across the interface without scattering by sharing the common Pb²⁺ sublattice between the perovskite and the chalcogenide, providing high charge mobility and enabling the photoelectric conversion efficiency to be maximized. Moreover, by increasing structural stability and enhancing crystallographic stability between the two materials, higher crystallinity can be maintained.

In the meantime, in one specific example, the first domain may have a cubic or polyhedral morphology, and the average size thereof may be in the range of 5 to 100 nm. The first domain may have an average size that is more specifically in the range of 8 to 80 nm, even more specifically in the range of 10 to 60 nm, and far more specifically in the range of 15 to 50 nm. The second domain may have a spherical or polyhedral morphology, and the average size thereof may be in the range of 1 to 20 nm. The second domain may have an average size that is more specifically in the range of 2 to 15 nm and even more specifically in the range of 3 to 10 nm. As described above, the NC, according to the present disclosure, may be composed of the cubic or polyhedral first domain having a size in the range of 5 to 100 nm and the spherical or polyhedral second domain having a size in the range of 1 to 20 nm, and may realize various optical properties through size control. In particular, the light absorption spectrum extends from the visible to the NIR region, so the NC is applicable to the fields of high-efficiency solar cells, infrared (IR) sensors, photocatalysis, and quantum optics.

In the meantime, the MHP-chalcogenide epitaxial heterostructure NC, according to the first embodiment of the present disclosure, may have an average PL decay time (τ_{avg}) of 5 ns or less at a temperature of 80 K, which is more preferably 4 ns or less, even more preferably 3 ns or less, and far more preferably 2 ns or less. This indicates that photoexcited charge carriers are rapidly separated and transferred through the interface. Such characteristics imply that the charge carriers are effectively separated and exhibit high charge mobility due to the epitaxial junction formed through lattice matching between the first domain (CsPbX₃) and the second domain (PbTe). In this case, the lower limit of the average PL decay time (τ_{avg}) is not particularly limited but may, for example, be 0.1 ns.

Additionally, the MHP-chalcogenide epitaxial heterostructure NC may have a PLQY of 5% or less at a temperature of 80 K, which is preferably 4.5% or less, more preferably 4% or less, even more preferably 3.5% or less, and far more preferably 3% or less. This indicates that the charge carriers move rapidly from the first domain to the second domain through the epitaxial junction, and rapid separation of holes and electrons occurs. The reduction in PLQY suggests that charge transport dominates over photoluminescence, which may serve as a key characteristic for high-efficiency photoelectric conversion and IR detection. In this case, the lower limit of PLQY is not particularly limited, but may, for example, be 0.1%. Such characteristics suggest that the MHP-chalcogenide epitaxial heterostructure NC, according to the present disclosure, is not just a photoluminescent material, but is applicable to high-performance optoelectronic devices capable of maximizing charge transfer and conversion. In particular, the NC of the present disclosure can be utilized in a wide range of applications, including solar cells, IR sensors, photocatalysis, and high-speed electronic devices.

Furthermore, a second embodiment of the present disclosure relates to a method of preparing the aforementioned MHP-chalcogenide epitaxial heterostructure NC and, in particular, relates to a method of preparing an MHP-chalcogenide epitaxial heterostructure NC, the method characterized by including the following steps: a) preparing a first domain precursor of an MHP satisfying CsPbX₃ (where X is a halide) and a second domain precursor of a PbTe chalcogenide, respectively; and b) growing a second domain on one surface of a first domain by reacting the first domain precursor with the second domain precursor, wherein the first and second domains form an epitaxial junction while achieving lattice matching.

First, Step a) of preparing the first domain precursor of the MHP satisfying CsPbX₃ (where X is a halide) and the second domain precursor of the PbTe chalcogenide, respectively, is to be described.

As mentioned above, the first domain precursor is an MHP satisfying CsPbX₃ (where X is a halide). The first domain precursor may be prepared by adding and reacting cesium oleate to and with a first reaction solution including PbX₂ (where X is a halide), a fatty acid, and a fatty amine.

In one example of the present disclosure, the PbX₂ serves as a precursor material for CsPbX₃, and specific examples thereof may include one or more selected from the group consisting of PbF₂, PbBr₂, PbCl₂, PbI₂, and the like. Preferably, PbBr₂ is used.

The fatty acid may be one or more selected from saturated fatty acids having 14 to 24 carbon atoms and unsaturated fatty acids having 14 to 24 carbon atoms, and specific examples thereof may include one or more selected from the group consisting of oleic acid (OA), palmitoleic acid, vaccenic acid, paullinic acid, and the like. Such a fatty acid may be added in an amount in the range of 0.01 to 10 mL, more preferably in the range 0.1 to 5 mL, and even more preferably in the range of 0.5 to 5 mL, with respect to 1 mol of the PbX₂.

The fatty amine may be one or more selected from saturated fatty amines having 14 to 24 carbon atoms and unsaturated fatty amines having 14 to 24 carbon atoms, and specific examples thereof may include one or more selected from the group consisting of hexylamine, octylamine, decylamine, dodecylamine, oleylamine (OlAm), and the like. Such a fatty amine may be added in an amount in the range of 0.01 to 10 mL, more preferably in the range of 0.1 to 5 mL, and even more preferably in the range of 0.5 to 5 mL, with respect to 1 mol of the PbX₂.

When preparing the first reaction solution, an additional solvent may be used. Any solvent can be used without limitations as long as it is non-reactive, and examples thereof may include 1-octadecene (ODE). The solvent may be added in an amount in the range of 1 to 100 mL, more preferably in the range of 10 to 50 mL, with respect to 1 mmol of the PbX₂.

When the first reaction solution is prepared, cesium oleate may be mixed and reacted therewith. In this case, the reaction temperature may be in the range of 100° C. to 200° C. Cesium oleate may be prepared by dissolving OA in cesium carbonate (Cs₂CO₃), and may be added in an amount in the range of 0.01 to 1 mL, more preferably in the range of 0.05 to 0.5 mL, with respect to 1 mL of the first reaction solution.

Additionally, the second domain precursor of the PbTe chalcogenide may be prepared by reacting a second reaction solution including Te powder and TOP. In this case, the TOP may be added in an amount in the range of 0.01 to 10 mL, more preferably in the range of 0.1 to 5 mL, and even more preferably in the range of 0.5 to 5 mL, with respect to 1 mol of the Te powder.

When preparing the second reaction solution, an additional solvent may be used. Any solvent can be used without limitations as long as it is non-reactive, and examples thereof may include ODE. The solvent may be added in an amount in the range of 1 to 100 mL, more preferably in the range of 5 to 50 mL, with respect to 1 mmol of the Te powder.

Once the respective precursors are prepared, Step b) of growing the second domain on one surface of the first domain by reacting the first domain precursor with the second domain precursor may then be performed.

To be more specific, Step b) may be performed by reacting a third reaction solution including the first domain precursor, the second domain precursor, lead oleate, and DDT. With respect to 1 mmol of the first domain precursor, the second domain precursor may be added in an amount in the range of 0.1 to 10 mmol, lead oleate may be added in an amount in the range of 0.01 to 10 mmol, and DDT may be added in an amount in the range of 0.01 to 10 mmol. More preferably, with respect to 1 mmol of the first domain precursor, the second domain precursor is added in an amount in the range of 0.5 to 2 mmol, lead oleate is added in an amount in the range of 0.1 to 0.5 mmol, and DDT is added in an amount in the range of 0.1 to 1 mmol. Within such ranges, the MHP-chalcogenide epitaxial heterostructure NC, in which the CsPbX₃ (112) and PbTe (111) planes form the epitaxial junction while achieving lattice matching, may be effectively prepared.

In this case, the reaction temperature may be in the range of 150° C. to 250° C., more preferably in the range of 200° C. to 250° C., and the reaction time may be in the range of about 5 to 20 min. However, such conditions are not necessarily limited thereto. When crystallization is promoted, the reaction solution is quenched using an ice bath and the like. During this process, the clear solution may rapidly change into a dark green product.

Thereafter, through a purification process, such as centrifugation, the MHP-chalcogenide epitaxial heterostructure NC may be obtained.

Hereinafter, MHP-chalcogenide epitaxial the heterostructure NC and the method of preparing the same, according to the present disclosure, are to be described in more detail through examples. However, the following examples are only a reference for describing the present disclosure in detail, and the present disclosure is not limited thereto and may be implemented in various forms.

Additionally, unless otherwise defined, all technical and scientific terms have the same meaning as commonly understood by those skilled in the art to which the present disclosure pertains. The terminology used herein is disclosed only for effectively describing particular examples and is not intended to limit the present disclosure. Furthermore, the unit of additives not particularly described herein may be wt %.

### Example 1

### a) Preparation of Cs-Oleate

ODE (17.5 ML), OA (2.5 mL), and Cs₂CO₃ (0.652 g) were added to a 100 mL round-bottom flask, followed by equipping the flask with a stirrer. The resulting mixture was dried under vacuum at 120° C. for 1 h, and then heated to and maintained at 150° C. in a nitrogen atmosphere until a clear solution was formed. Such produced Cs-oleate was stored for later use.

### b) Preparation of PbBr₂ Solution

ODE (3.0 ML), OA (0.5 mL), OlAm (0.5 mL), and PbBr₂ (0.0734 g) were added to a 100 mL round-bottom flask, followed by equipping the flask with a stirrer. The resulting solution was dried under vacuum at 120° C. for 1 h, and then heated to and maintained at 150° C. in a nitrogen atmosphere until a clear solution was formed. Such a prepared PbBr₂ solution was stored for later use.

### c) Preparation of TOP-Te Solution

ODE (15 mL) and Te powder (191 mg) were added to a 50 mL round-bottom flask, followed by equipping the flask with a stirrer. The resulting product was dried under vacuum at 120° C. for 1 h, followed by injecting TOP (4 mL), and stirred under vacuum until the Te powder fully dissolved. Such a prepared TOP-Te solution was stored for later use.

### d) Preparation of CsPbBr₃ Cluster Precursor

The PbBr₂ solution (4 mL) was transferred into a glass vial equipped with a stirrer, and then pre-heated Cs-oleate (0.2 mL) was rapidly injected. The resulting mixture was centrifuged at 8,000 rpm for 10 min to collect white waxy precipitates (12-faceted rhombic dodecahedron NCs) exhibiting an absorption peak at λ_{absorption}=405 nm. Such precipitates were dispersed in ODE (1 mL) and used in later experiments.

### e) Synthesis of CsPbBr₃—PbTe Epitaxial Heterostructure NCs

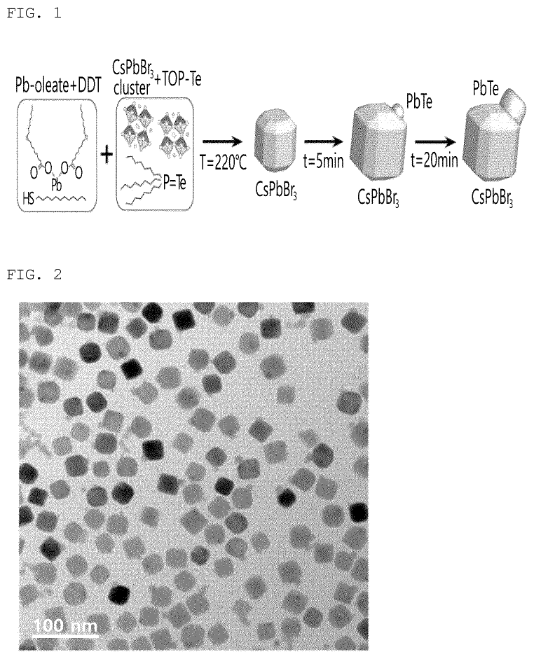

ODE (4.0 mL) and Pb-oleate (26 μL) were added to a 50 mL round-bottom flask and degassed at 120° C. under vacuum for 10 min. The temperature was then raised to 220° C. in a nitrogen atmosphere. DDT (25 μL) was injected, followed by additionally injecting TOP-Te (100 μL) and the CsPbBr₃ cluster precursor (1.0 mL) to synthesize CsPbBr₃—PbTe heterostructure NCs (FIG. 1). The resulting mixture was heated for 5 to 20 min to promote crystallization of the PbTe phase and then quenched in an ice bath. During this process, the clear solution rapidly changed into a dark green product. After the subsequent centrifugation at 11,000 rpm for 20 min, the resulting precipitates were dispersed in toluene (4 mL) for characterization.

The yield of CsPbBr₃—PbTe epitaxial heterostructure NCs was measured to be about 97%, while the yield of CsPbBr₃ NCs without PbTe domain formation was only about 3%.

### [Comparative Example 1] Synthesis of Pristine CsPbBr₃ NCs

ODE (4.0 mL) was added to a 50 mL round-bottom flask and degassed at 120° C. under vacuum for 10 min. The temperature was then raised to 220° C. in a nitrogen atmosphere. After injecting the CsPbBr₃ cluster precursor (1.0 mL), the resulting product was heated for 5 min and quenched. NCs were isolated by repeating centrifugation (at 11,000 rpm for 30 min) twice, followed by dispersing the resulting precipitates in toluene (4 mL) for further characterization.

### [Evaluation of Characteristics]

### a) Evaluation Method

Bright-field TEM images were obtained using a JEOL-2100F electron microscope (at 200 keV), and analysis of STEM-EELS and the corresponding mappings were performed using a JEOL monochromated ARM-200F (NEO-ARM, DJ105) operated at 200 kV. Electron energy core loss spectra were collected using a Gatan Imaging Filter Continuum HR-1066 spectrometer, and spectrum images were acquired using Gatan Digital Micrograph software, with a dispersion of 1.5 eV per channel and a collection aperture of 5 mm in diameter. The spectrum images were acquired at a resolution of 24×20 pixels with an acquisition time of 0.1 s per pixel. XRD patterns were recorded using a Bruker AXS D8 diffractometer with Cu-Ko radiation (λ=1.54 Å). XPS spectra were obtained using a Thermo Fisher Scientific/K-Alpha+ spectrometer equipped with a monochromatic Al Kα X-ray source (hν=1486.6 eV). UV-Vis absorbance spectra and PL spectra were measured in a room-temperature environment using a Shimadzu UV-2600 spectrophotometer and a Hitachi F-7000 fluorescence spectrophotometer, respectively. NIR absorption spectra were measured using a Shimadzu SolidSpec-3700 diffuse reflectance UV-Vis-NIR spectrophotometer, with InGaAs and PbS detectors for the NIR region. TRPL decay spectra were acquired with a 375-nm laser as the excitation source, using an Edinburgh FS-5 spectrophotometer and time-correlated single photon counting (TCSPC, Horiba Scientific). Additionally, fluorescence decay curves were fitted using a bi- or tri-exponential model, depending on the PL decay mechanism. The general equation for PL decay is as follows.

$$I ( t ) = C + {α}_{1} exp ( - t / {τ}_{1} ) + {α}_{2} exp ( - t / {τ}_{2} ) + {α}_{3} exp ( - t / {τ}_{3} ) \qquad ( 1 )$$

Here, I(t), τ, a, and C denote the PL intensity, lifetime, pre-exponential factor, and constant, respectively. The average lifetime (τ_{avg}) was calculated as the average value of the tri-exponential decay.

$${τ}_{avg} = \frac{{α}_{1} {τ}_{1}^{2} + {α}_{2} {τ}_{2}^{2} + {ατ}_{3}^{2}}{{α}_{1} {τ}_{1} + {α}_{2} {τ}_{2} + {α}_{2} {τ}_{2}} = {f}_{1} {τ}_{1} + {f}_{2} {τ}_{2} + {f}_{3} {τ}_{3} + A \qquad ( 2 )$$

Here, f denotes the fractional contribution of each decay component, while A denotes a constant. The accuracy of the fitting was evaluated by the χ² value, yielding values between 1 and 1.2. Low-temperature PL spectroscopic measurement was performed using a spectrofluorometer (Edinburgh FS-5) in a temperature range of 80 to 300 K. UPS spectra were measured using Nexsa G2 (Thermo Fisher Scientific) with He I radiation (hν=21.2 eV).

### b) Analysis of Characteristics

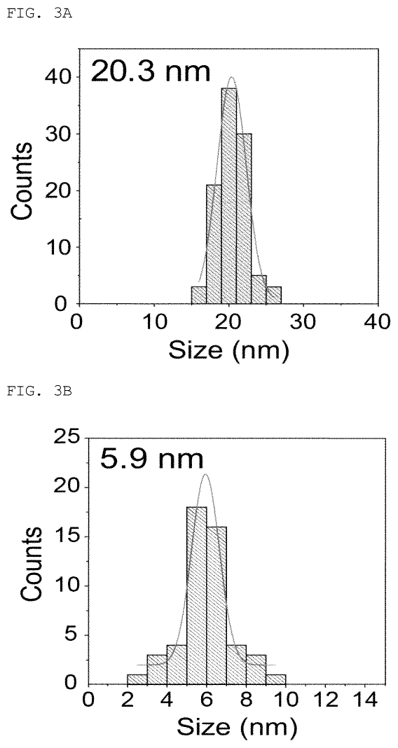

The TEM image of FIG. 2 confirmed that the synthesized CsPbBr₃ NCs had a uniform cubic morphology and a structure in which PbTe NCs were formed at each corner. In particular, the PbTe domain was selectively formed only at a specific corner of the CsPbBr₃ cube, indicating that the position thereof was uniformly maintained. The measured average edge lengths were 20.1±2.5 nm for the CsPbBr₃ NCs and 5.9±0.6 nm for the PbTe NCS, exhibiting relatively uniform distributions. This indicates that the formation of the CsPbBr₃—PbTe heterostructure NCs was precisely controlled (FIG. 3).

The crystalline phase and facet characteristics of such nanostructures were further analyzed using HRTEM images and FFT patterns (FIGS. 4A to 4D). The HRTEM images clearly showed a truncated cubic CsPbBr₃ host NC with various facets (FIG. 4A). Initially, the PbTe domain exhibited a spherical morphology, which transformed into a rectangular morphology as the reaction time increased from 5 min, leading to improved crystallinity (FIGS. 4B and 5).

The analysis results of the selected area FFT patterns for CsPbBr₃ (Domain 1 of the NC) and PbTe (Domain 2 of the NC) in the HRTEM image presented in FIG. 4A are shown in FIGS. 4C and 4D, respectively. The FFT pattern for Domain 1 presented in FIG. 4C showed d-spacings of 0.59, 0.41, and 0.58 nm corresponding to the respective (002), (1-12), and (1-10) planes of the orthorhombic CsPbBr₃ phase (PDF #01-072-7929, a space group of Pbnm with the following lattice parameters: a=8.207 Å, b=8.255 Å, and c=11.759 Å). It was confirmed that the (002) and (1-10) planes were perpendicular to each other, whereas the (1-12) plane formed an angle of 45° with respect to these planes when viewed along the direction (see the atomic model in FIG. 6).

In contrast, the FFT pattern (FIG. 4D) for Domain 2 in FIG. 4A showed d-spacings of 0.38, 0.33, and 0.46 nm corresponding to the respective (−111), (00-2), and (1-10) planes of the cubic PbTe phase (PDF #03-065-8325, a space group of Fm-3m with the following lattice parameter: a=6.54 Å). Notably, the d-spacing (d112_{CsPbBr3}=0.41 nm) of the CsPbBr₃ (112) plane and the d-spacing (d111_{CsPbBr3}=0.38 nm) of the PbTe (111) plane are closely matched. In addition, mutual orientation between the CsPbBr₃ (1-12) plane and the PbTe (−111) plane suggests that the (111) facets of the PbTe domain promoted epitaxial growth on the (112) facets of the orthorhombic CsPbBr₃ NCs. This indicates that both planes were aligned with each other at the coherent interface between the CsPbBr₃ and PbTe crystals. The atomic model illustrating the CsPbBr₃—PbTe heterostructure is presented in FIG. 6.

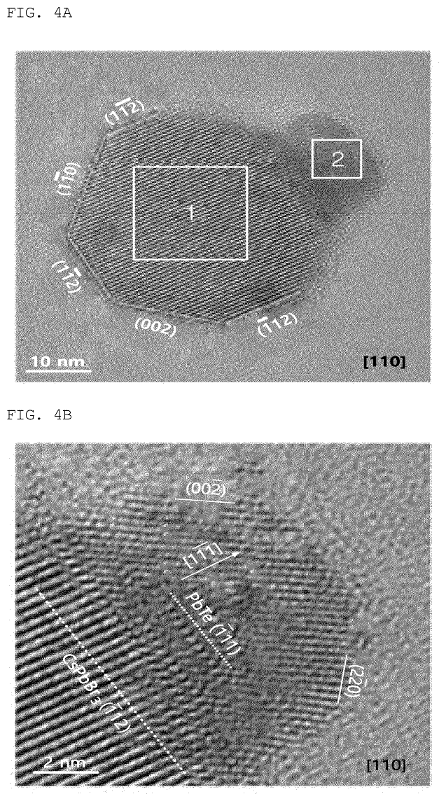

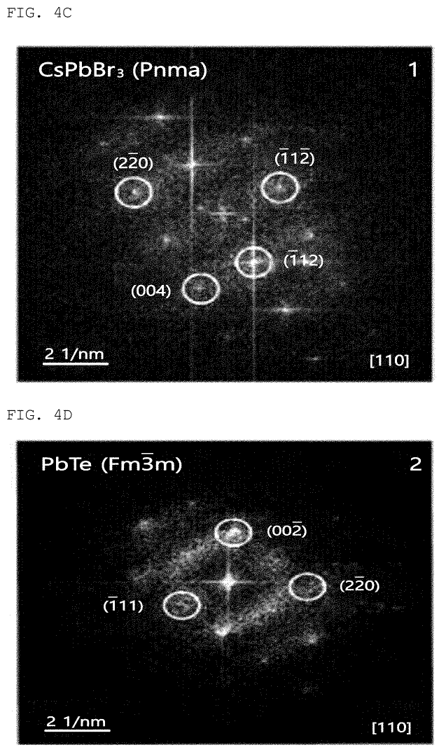

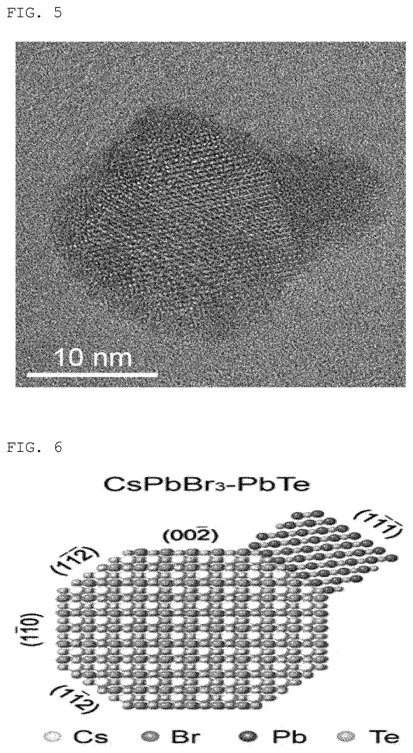

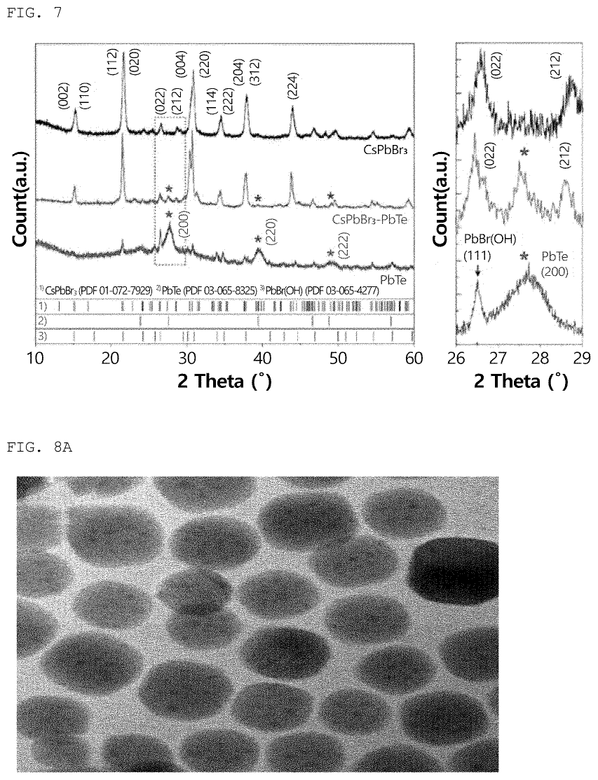

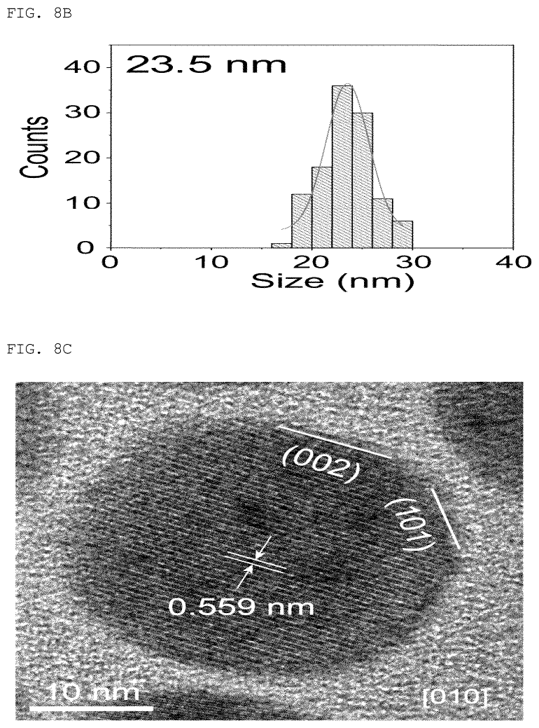

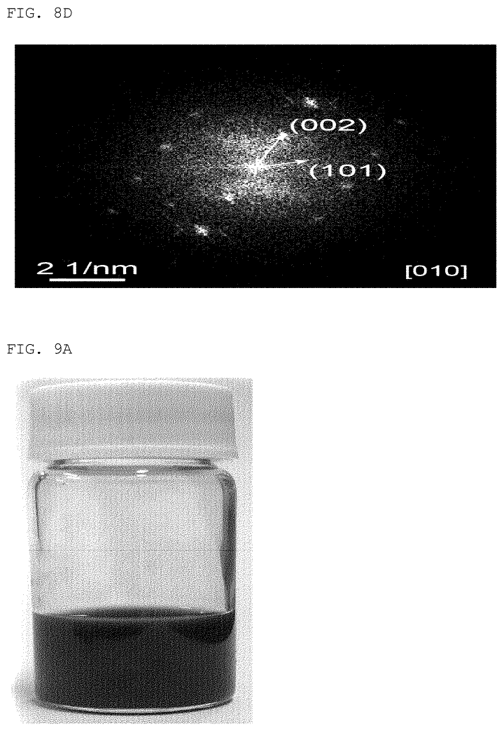

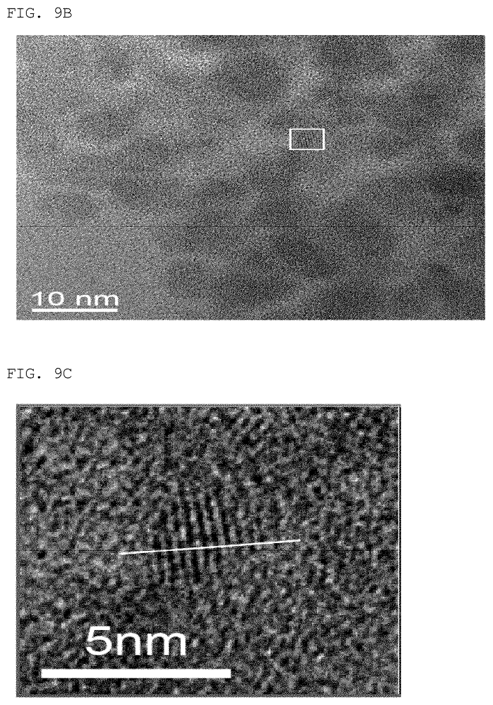

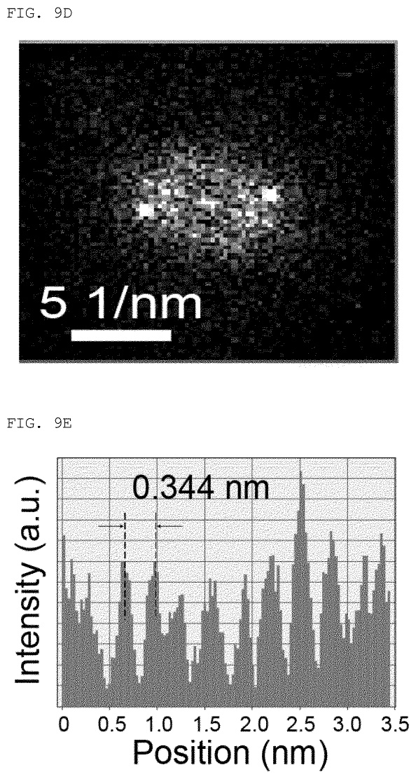

The crystal structure of the CsPbBr₃—PbTe heterostructure NCs was confirmed through powder XRD patterns, with comparison to the patterns of the pristine CsPbBr₃ and PbTe NCs (FIG. 7). The pristine CsPbBr₃ NCs were synthesized without the precursors (Pb-oleate, DDT, and TOP-Te) used for the formation of PbTe in the synthesis process, whereas the PbTe NCs were obtained by dissolving the CsPbBr₃—PbTe heterostructure NCs in a dimethylformamide (DMF) solvent (FIGS. 8 and 9).

The pristine CsPbBr₃ NCs exhibited a well-defined orthorhombic phase, and no peak shifts or additional peaks indicative of potential byproducts were observed. Interestingly, the intensities of the (112) and (020) planes were significantly stronger than those of the (002) and (110) planes, implying that the intermediate polyhedral nanostructure with eight {112} facets was stabilized during the synthetic process.

Similarly, the CsPbBr₃—PbTe heterostructure NCs also exhibited strong (112) and (020) peaks related to the orthorhombic CsPbBr₃ phase. Furthermore, broad (200), (220), and (222) peaks corresponding to the cubic PbTe phase were additionally observed. These results confirm that the CsPbBr₃—PbTe heterostructure NCs with an epitaxial interface between the CsPbBr₃ {112} and PbTe {111} facets were formed.

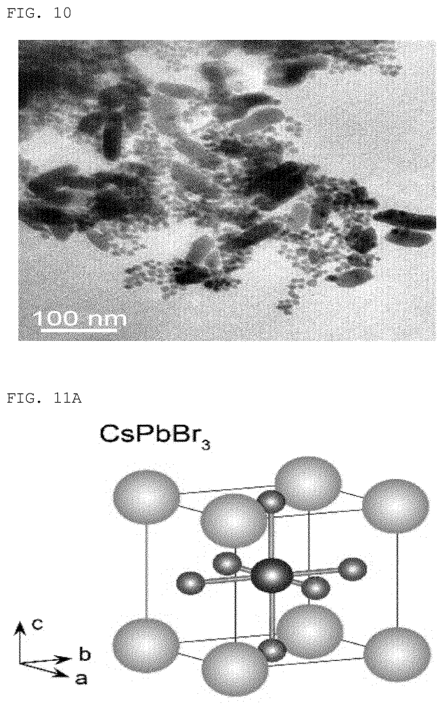

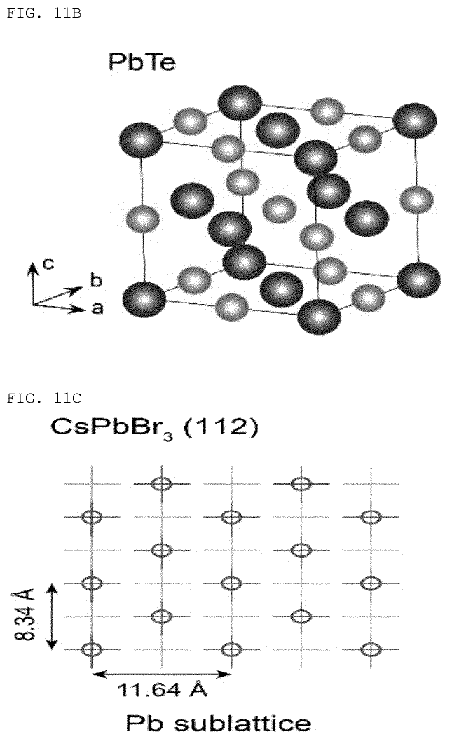

Notably, the diffraction pattern of the PbTe NCs contained additional peaks assigned to the orthorhombic PbBr(OH) phase (PDF #03-065-4277), which were likely generated during the dissolution process of the CsPbBr₃ domain (FIG. 10). The PbBr(OH) phase with NCs of several hundred nanometers in size exhibited significantly narrow and sharp peaks compared to the broad peaks of the PbTe phase, confirming the presence of nanoscale PbTe crystals.

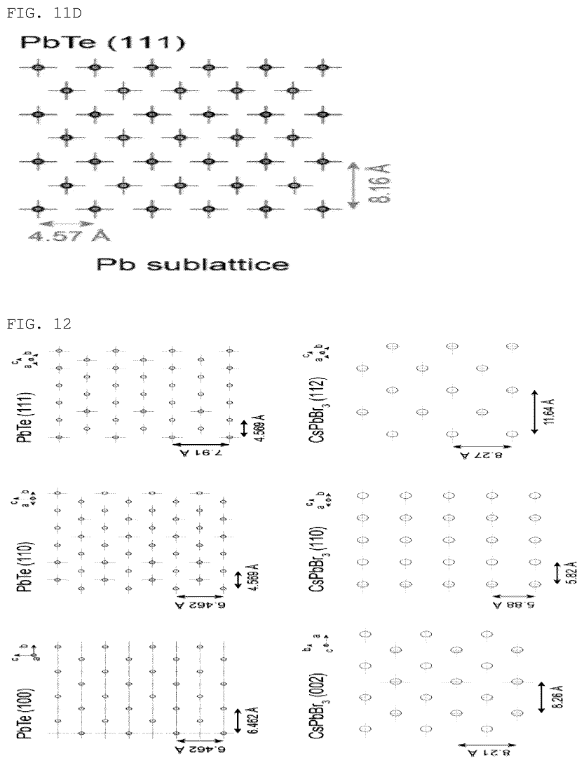

For a better understanding of the epitaxial growth of the PbTe phase at the heterojunction and the resulting morphological evolution, atomic models depicting the structure of each crystalline phase and the corresponding Pb sublattices are presented in FIG. 11. Both CsPbBr₃ and PbTe crystal structures contain a common Pb sublattice, thus enabling the growth of the PbTe domain directly on the common Pb²⁺ subnetwork of the CsPbBr₃ NCs, which promotes structural continuity across the entire perovskite and chalcogenide interface. Such continuity is formed due to an energetically stable environment with chemically compatible bonding and composition.

Furthermore, lattice matching is essential to achieve high-quality epitaxial growth with minimized lattice strain at the heterojunction. To analyze lattice matching between the CsPbBr₃ and PbTe crystals, the d-spacings of the Pb sublattices for several combinations of different planes were compared (FIGS. 11C, 11D, and 12). The d-spacing of CsPbBr₃ {112} planes closely matched that of PbTe {111} planes, which was consistent with the HRTEM and FFT analysis results.

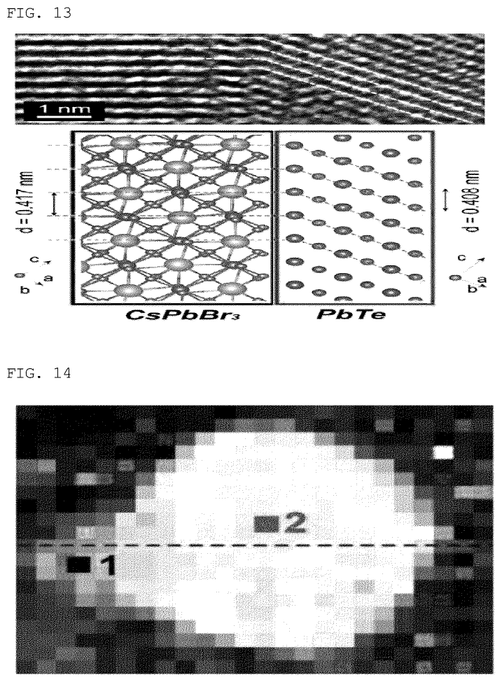

From the HRTEM image at a higher magnification, structural continuity across the entire heterojunction of the CsPbBr₃—PbTe heterostructure NCs was clearly confirmed (marked with yellow dashed lines in FIG. 13). In addition, the atomic model describing the heterojunction also supported the close lattice matching between the CsPbBr₃ {112} and PbTe {111} facets.

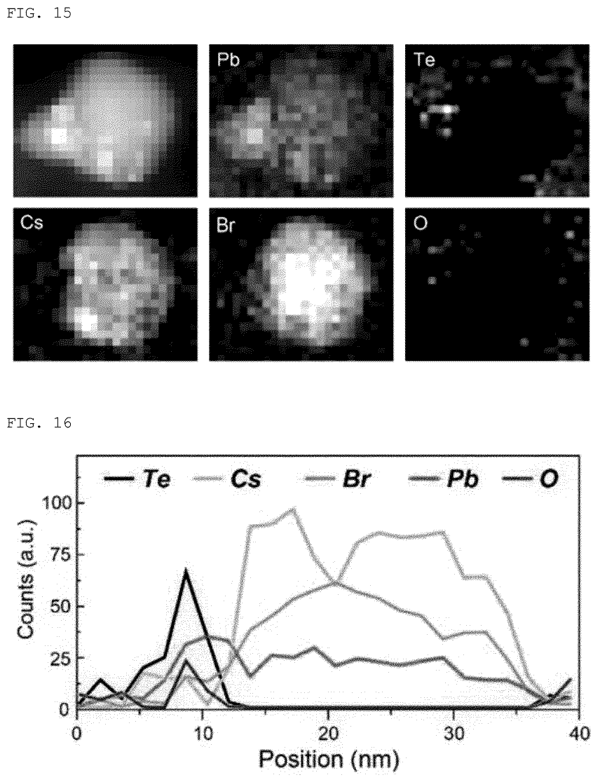

To further clearly analyze the morphology and phase composition of the CsPbBr₃—PbTe heterostructure NCs, STEM-EELS analysis was performed (FIGS. 14 to 17). From the spatially resolved STEM-EELS elemental maps, it was confirmed that Cs-M_{4,5}, Pb-M_{4,5}, and Br-L_{2,3} signals depicted square-shaped CsPbBr₃ NCs. Additionally, the presence of the PbTe domain at the corner of the CsPbBr₃ NC was demonstrated by the EELS maps for Pb-M_{4,5} and Te-M_{4,5} signals (FIGS. 14 and 15).

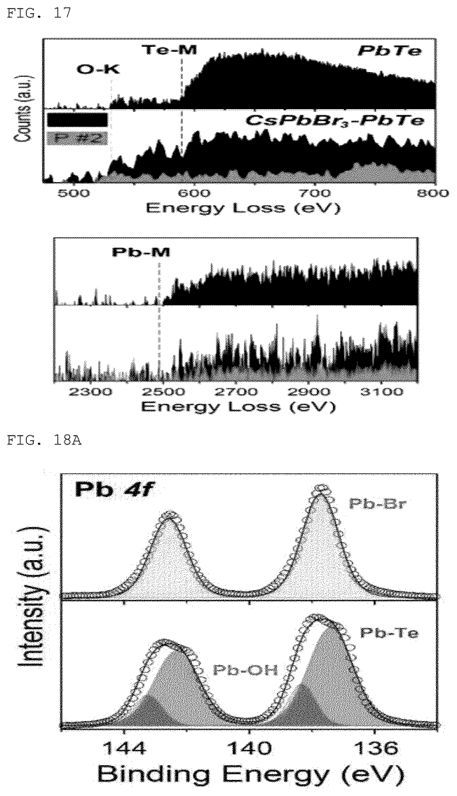

As a result of analyzing a line profile measured along the dashed line marked in FIG. 14, elemental Te was not detected within the CsPbBr₃ domain, implying that Te was neither adsorbed onto the surface of the CsPbBr₃ NCs nor incorporated into the crystalline lattice (FIG. 16). In the case of the CsPbBr₃—PbTe heterostructure NCs, core-loss spectra were extracted from P #1 (PbTe domain) and P #2 (CsPbBr₃ domain) points marked in FIG. 14 and analyzed (FIG. 17). A distinct Te-M_{4,5} signal was observed at 572 eV in the case of P #1, which was consistent with the signal of the PbTe NCs, whereas no detectable Te signal was observed in the case of P #2 (CsPbBr₃ domain). Furthermore, strong Pb-M_{4,5} signals were observed for both PbTe and CsPbBr₃ domains. In particular, the weak O-K edge observed at 528 eV was construed as resulting from trace impurities such as oleic acid and oxidized Te compounds (for example, TeO₂ and (HO)₂TeO). The analysis result of the elemental map for the O-K edge signal confirmed the distribution of oxygen around the CsPbBr₃—PbTe heterostructure NC (FIG. 15).

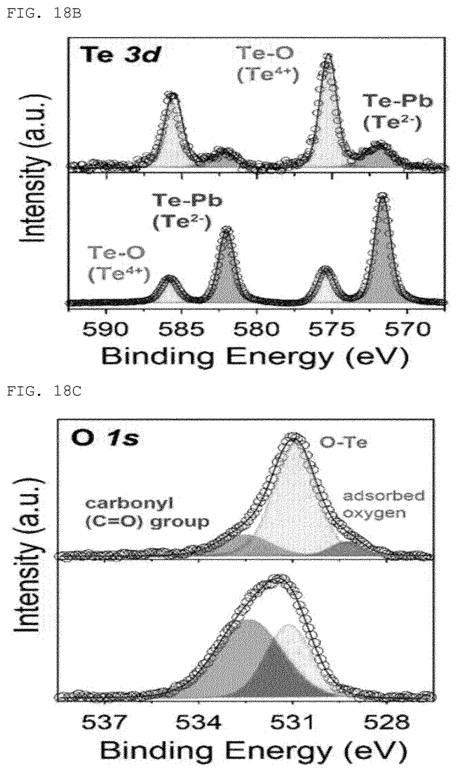

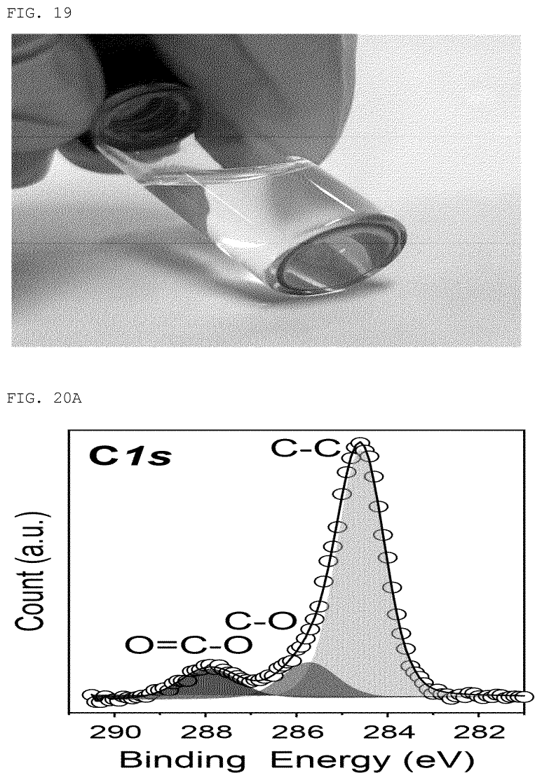

To examine the chemical bonding properties of the CsPbBr₃—PbTe heterostructure NCs in more detail, XPS analysis was performed. Further detailed analysis was conducted through peak fitting calculation using Gaussian-Lorentzian curves. FIGS. 18A to 18C show representative high-resolution XPS spectra of the CsPbBr₃—PbTe heterostructure NCs (top panels) and the PbTe NCs (bottom panels).

In the case of the CsPbBr₃—PbTe heterostructure NCs, a distinct Pb 4f doublet was observed at binding energies of 142.6 eV (Pb 4f_{5/2}) and 137.8 eV (Pb 4f_{7/2}), without distinct shoulder peaks. This suggests that both Pb—Br and Pb—Te binding energies are nearly identical (FIG. 18A). In contrast, in the Pb 4f XPS spectrum of the PbTe NCs, shoulder peaks (Pb 4f_{5/2} at 143.2 eV and Pb 4f_{7/2} at 138.3 eV) were observed at low binding energies, alongside the major peak attributed to the Pb—Te bond. Such additional peaks were construed as originating from the divalent state of the Pb—O bond caused by z-type Pb-oleate ligands in a chelating bidentate coordination.

As supporting evidence, the Pb—Pb distance measured on the (111) plane of PbTe was found to be 4.57 Å, which was confirmed to be wider than the density (4 to 4.6 chains/nm-2) of alkyl chains sterically hindered on planar surfaces. This suggests the presence of the Pb-oleate ligands that form the Pb—O bond in the PbTe NCs.

In the meantime, the Te 3d XPS spectrum was deconvoluted into two doublets, revealing two oxidation states of Te (Te²⁻ and Te⁴⁺) with different chemical environments (FIG. 18B). It is presumed that these peaks correspond to the Te—Pb (Te 3d_{3/2} at 582.5 eV and 3d_{5/2} at 572.1 eV) and Te—O (Te 3d_{3/2} at 585.9 eV and 3d_{5/2} at 575.4 eV) bonds, respectively.

Te²⁻ is the only oxidation state present in the stoichiometric PbTe phase. However, the PbTe surface is readily oxidized to form a native TeO₂ layer, exhibiting the additional chemical state of Te⁴⁺. This is construed as resulting from Te having more metallic characteristics than other chalcogen elements such as sulfur(S) and selenium (Se). Similarly, in the present disclosure, the formation of white TeO₂ precipitates at the bottom of the glass vial was also observed during the storage of the TOP-Te precursor solution. This indicates that Te tends to be oxidized (FIG. 19). Thus, the oxidation of stoichiometric PbTe NCs or residual TOP-Te under ambient conditions may lead to the formation of trace impurities such as (HO)₂TeO and TeO₂.

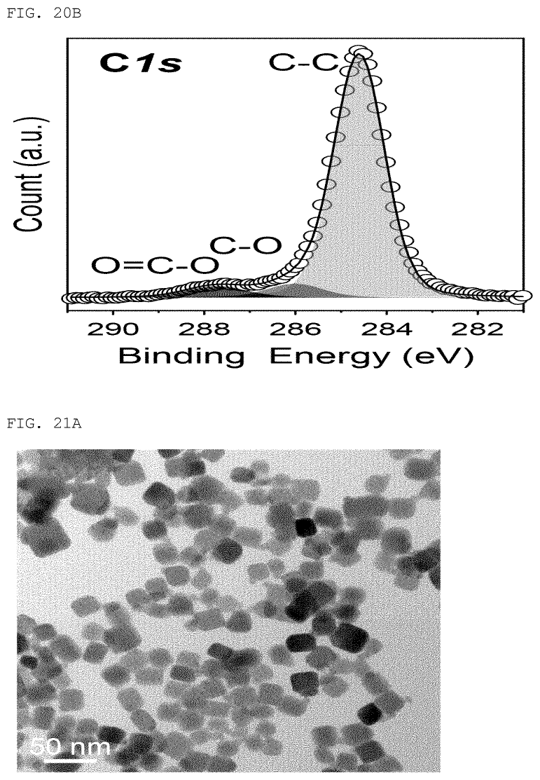

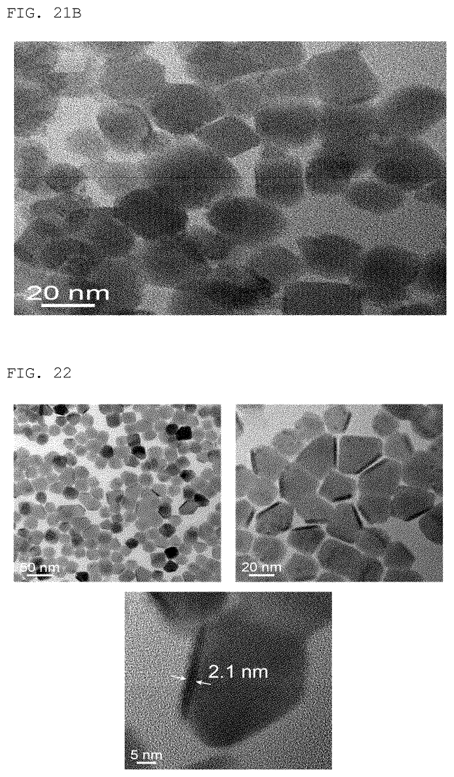

In this context, the O 1s XPS spectrum of the CsPbBr₃—PbTe heterostructure NCs exhibited a major peak corresponding to the O-Te bond (O 1s at 530.9 eV), which was significantly reduced after the dissolution process of the CsPbBr₃ NCs (FIG. 18C). This result is consistent with the observation of the Te—O bond in the Te 3d XPS spectrum. Furthermore, the O 1s peaks, additionally observed at higher and lower binding energies (532.5 eV and 529.2 eV), may correspond to the carboxylic group (—COOH) of OAs and 02 molecules adsorbed onto the surface of the CsPbBr₃—PbTe heterostructure NCs, respectively. Also, in the C 1s XPS spectrum, C—C(284.6 eV), C—O (286.1 eV), and O═C—O (287.7 eV) bonds were observed, confirming the presence of coordinated ligands on the surface of the NCs (FIG. 20). Therefore, these results clearly demonstrate the successful formation of the CsPbBr₃—PbTe heterostructure NCs.

To gain further insights into the chemical pathway involved in the formation of a secondary PbTe phase on the CsPbBr₃ NCs, the respective roles of Pb-oleate and DDT were examined under conditions in the absence of either Pb-oleate or DDT during the synthesis process of the CsPbBr₃—PbTe heterostructure NCs.

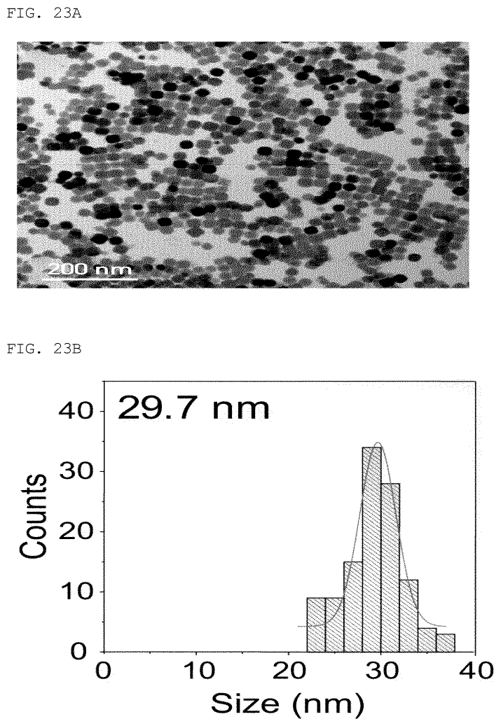

In the absence of Pb-oleate, the CsPbBr₃—PbTe heterostructure NCs were hardly formed, and irregularly shaped and sized CsPbBr₃ NCs were obtained instead (FIG. 21). This suggests that the Pb component within the CsPbBr₃ clusters hardly reacted with TOP-Te under these conditions, failing to induce the crystallization of the PbTe phase.

Interestingly, in the absence of DDT, a small fraction (<30%) of the CsPbBr₃—PbTe heterostructure NCs was formed, showing a thin PbTe layer (about 3 nm thick) compared to that formed in the presence of DDT. In this case, the CsPbBr₃ domain was formed in a truncated cubic morphology (FIGS. 2, 4, and 22). Although these samples showed well-defined heterostructures, it was observed that the CsPbBr₃ domains aggregated and merged into large clusters. This suggests that DDT plays a crucial role in achieving uniform reactivity of the Pb component with TOP-Te at specific facets of the CsPbBr₃ domain.

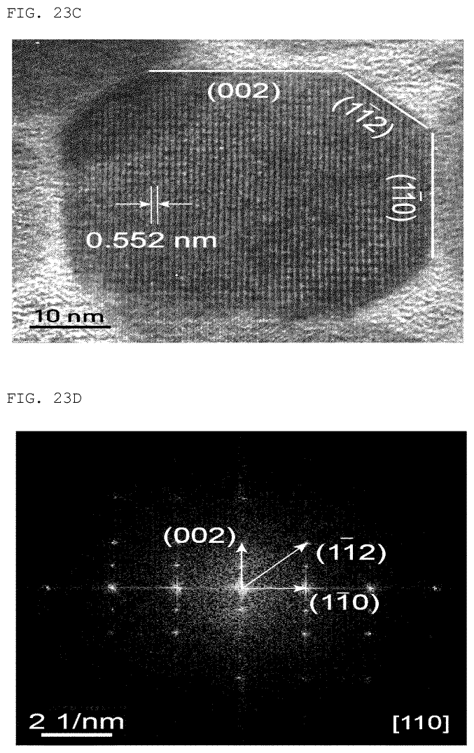

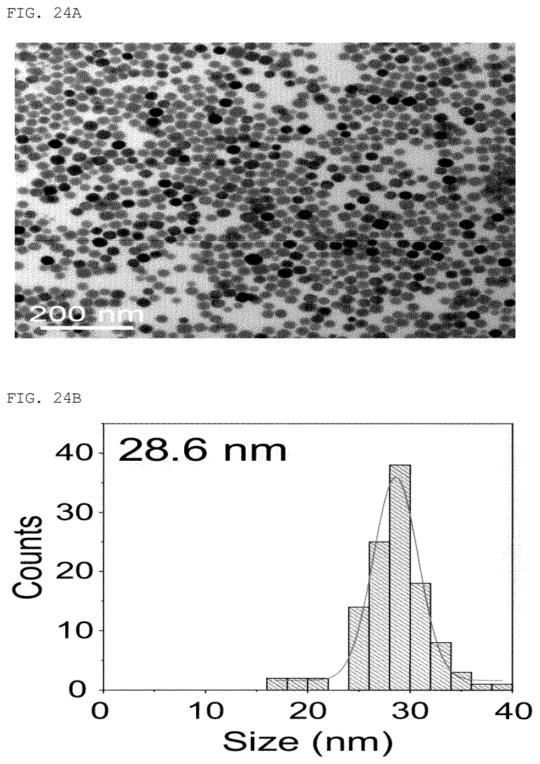

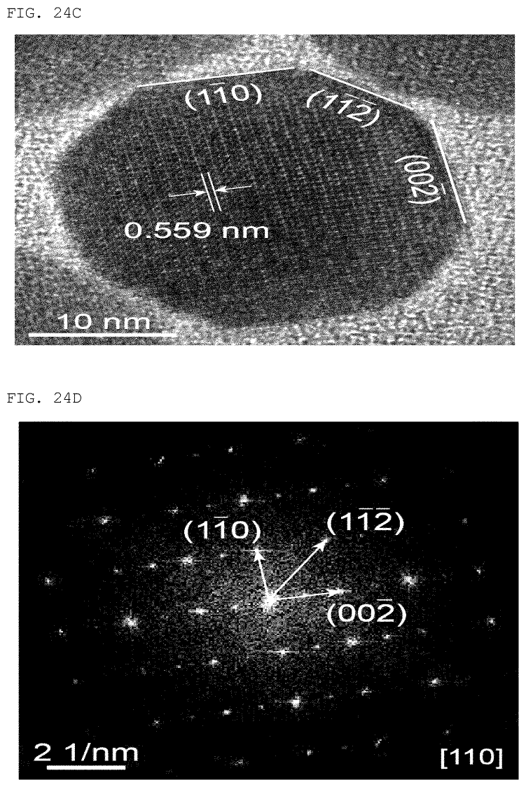

In particular, the pristine CsPbBr₃ NCs exhibited an isotropic spherical morphology with no preferential facet growth. However, highly uniform CsPbBr₃ NCs with precisely controlled {112}, {002}, and {110} facets were formed in the presence of both Pb-oleate and DDT, whereas a mixture of isotropic and polyhedral NCs was produced in the presence of only Pb-oleate (FIGS. 23 and 24).

Therefore, these results indicate that DDT also plays a crucial role in the formation of uniform CsPbBr₃ polyhedral NCS with controlled facets and the subsequent growth process, which is consistent with the characteristics observed in the CsPbBr₃—PbTe heterostructure NCs.

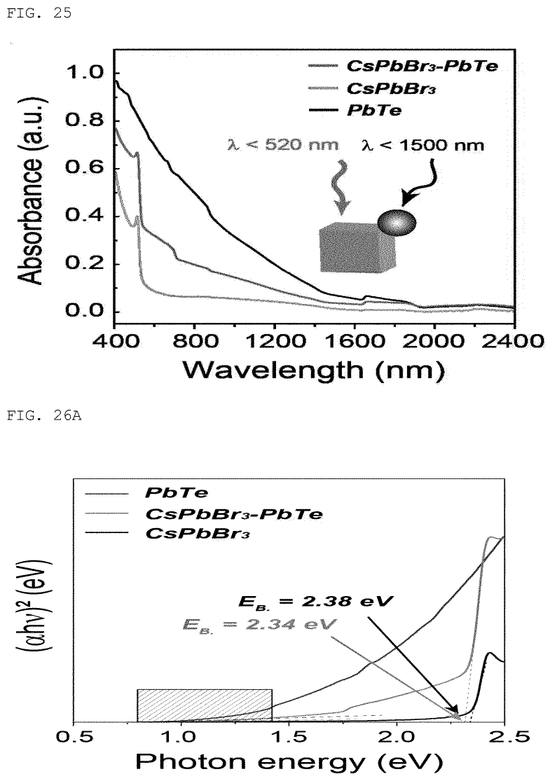

The UV-Vis-NIR absorption spectrum of the pristine CsPbBr₃ NCs exhibited an excitonic absorption edge at λ=512 nm, which was consistent with a band-gap energy (E_{b}=2.42 eV) calculated through a Tauc plot. In contrast, almost no absorption was detected in the region where λ>512 nm (FIGS. 25 and 26).

In contrast, the CsPbBr₃—PbTe heterostructure NCs exhibited a significantly increased absorption tail in the range of λ=512 to 1500 nm, which was identified as originating from the added PbTe phase. Pristine PbTe NCs exhibit strong absorption across the entire visible and NIR regions, demonstrating a direct correlation with the enhanced absorption observed in the heterostructure NCs.

Interestingly, the absorption spectrum of the PbTe NCs displayed an absorption edge at λ=1500 nm (E_{b}^{NC}=0.82 eV), revealing a significant blue shift compared to the bulk counterpart (E_{b}^{bulk}=0.32 eV). This is attributed to the strong quantum confinement effect resulting from the NC size (<10 nm) being smaller than the exciton Bohr radius (a_{Bohr}^{PbTe}=152 nm).

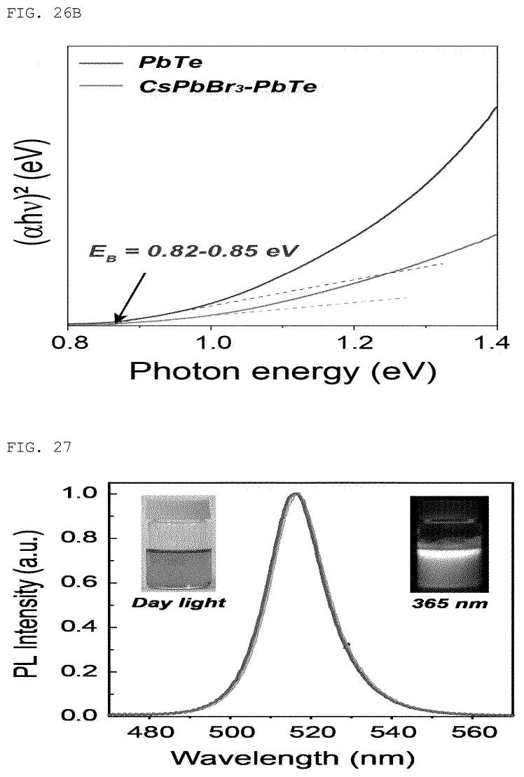

Nevertheless, the CsPbBr₃—PbTe heterostructure NCs still exhibited a narrow and weak PL emission at λ=520 nm, and the FWHM was measured to be 18 nm (FIG. 27). The pristine CsPbBr₃ NCs showed the maximum PL at a similar wavelength (λ=522 nm), and the PLQY was about 15%. However, in the CsPbBr₃—PbTe heterostructure NCs, the PLQY was significantly reduced to about 2%.

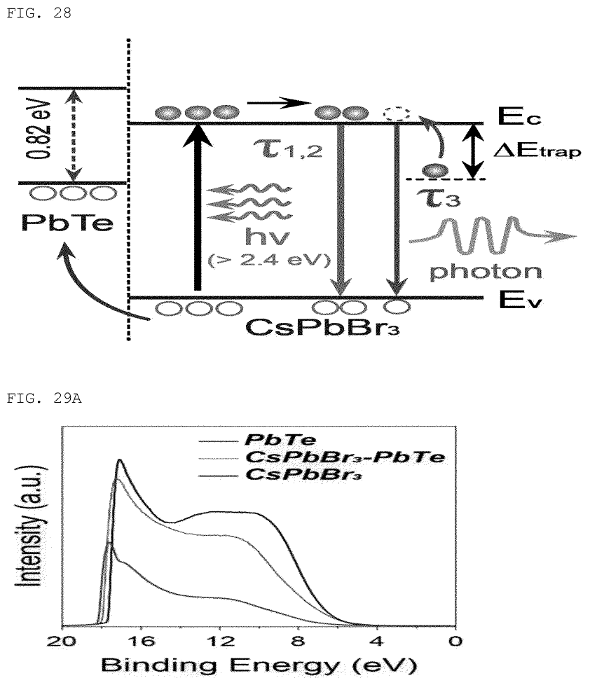

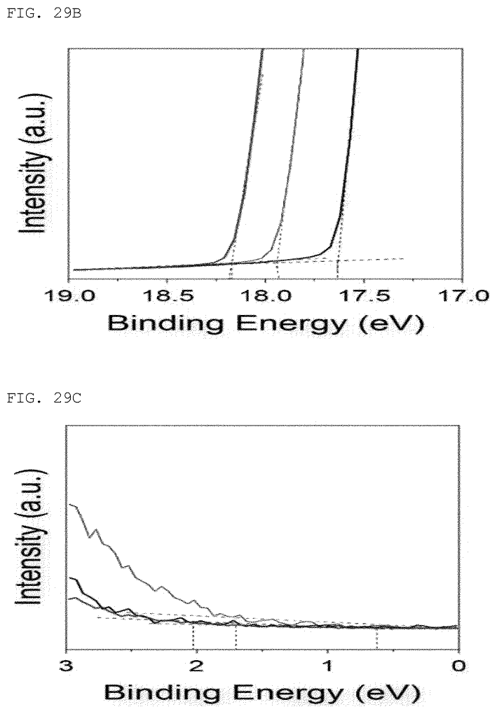

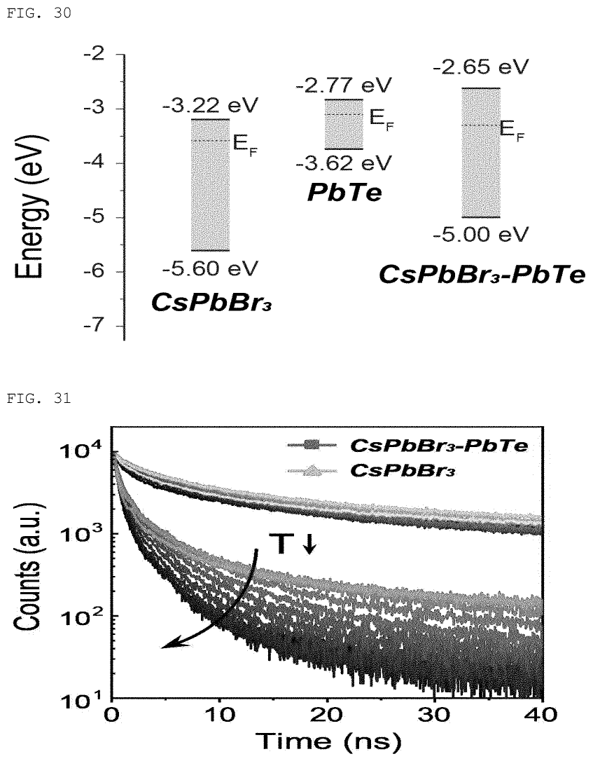

Such a reduction in PL emission suggests that hole migration from the CsPbBr₃ domain to the PbTe domain smoothly occurred in the CsPbBr₃—PbTe heterostructure NCs, along with efficient and fast electron and hole separation through the interface (FIGS. 28, 29, and 30, and Table 1).

Table 1 below summarizes the analysis results of the UPS spectra, showing the valence band maximum value (E_{VBM}), conduction band minimum value (E_{CBM}), band-gap energy (E_{g}), and Fermi energy (E_{F}) of the CsPbBr₃—PbTe heterostructure NCs, pristine CsPbBr₃ NCs, and PbTe NCs.

TABLE 1

| | | Low E | | | | |
|---|---|---|---|---|---|---|
| | E_{cut-off} (eV) | tail (eV) | E_{VBM} (eV) | E_{CEM} (eV) | E_{g} (eV) | E_{F} (eV) |
| CsPbBr₃—PbTe | 17.918 | 1.694 | −4.996 | −2.649 | 2.347 | −3.302 |
| CsPbBr₃ | 17.637 | 2.021 | −5.604 | −3.22 | 2.384 | −3.583 |
| PbTe | 18.207 | 0.608 | −3.621 | −2.771 | 0.85 | −3013 |

Additionally, the charge carrier dynamics were further examined through the temperature-dependent photophysical properties of the CsPbBr₃—PbTe heterostructure NCs using cryogenic PL spectroscopy (FIGS. 31 to 36).

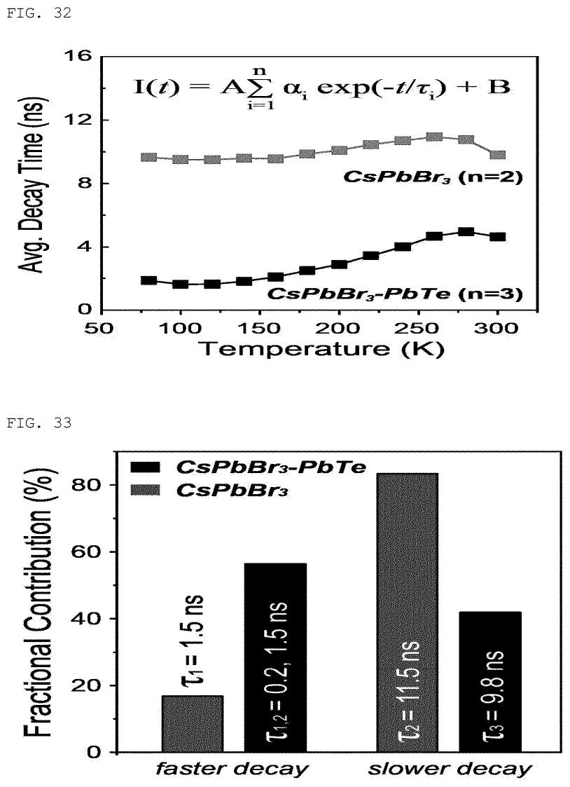

To understand the effect of charge transport on the carrier dynamics in the CsPbBr₃ domain, the temperature-dependent TRPL decay spectra were analyzed at λₑₘᵢₛₛᵢₒₙ=520 nm using a multiexponential decay model (FIGS. 31 to 33). In particular, for the decay curves of the CsPbBr₃—PbTe heterostructure NCs, the tri-exponential model exhibited a more accurate fit than the existing bi-exponential model commonly used for the analysis of the pristine CsPbBr₃ NCs (FIG. 32 and Table 2).

The average PL decay time (τ_{avg}) was 9.79 ns in the case of the pristine CsPbBr₃ NCs, but was significantly reduced to 4.65 ns at T=300 K in the case of the CsPbBr₃—PbTe heterostructure NCS. Additionally, the fractional contribution of the fast radiative decay component in the CsPbBr₃—PbTe heterostructure NCs increased significantly from about 17% for the pristine CsPbBr₃ NCs to about 58% (FIG. 33). In the pristine CsPbBr₃ NCS, a slow decay component associated with a thermally activated trapping process dominates. In contrast, in the CsPbBr₃—PbTe heterostructure NCs, most of the photoexcited charge carriers rapidly transferred from the CsPbBr₃ domain to the PbTe domain, while the remaining carriers relaxed to the ground-state excitons through radiative recombination. Consequently, the ultrafast interfacial transfer of the photoexcited charge carriers effectively suppressed the slow PL decay.

Nonetheless, the average PL decay time of the CsPbBr₃—PbTe heterostructure NCs was significantly reduced from 4.6 ns at T=300 K to 1.9 ns at T=80 K, suggesting the presence of a considerable energy barrier for the thermally activated recombination process.

TABLE 2

| | |
|---|---|
| CsPbBr₃—PbTe | CsPbBr₃ |

Temperature (K)

| | 80 K | 300 K | 80 K | 300 K |
|---|---|---|---|---|
| τ₁ (ns) | 0.2215 | 0.1681 | 1.1047 | 1.4624 |
| τ₂ (ns) | 1.2374 | 1.501 | 11.5949 | 11.4732 |
| τ₃ (ns) | 6.6882 | 9.7975 | — | — |
| B₁ (%) | 41.21 | 24.96 | 18.56 | 16.77 |
| B₂ (%) | 39.52 | 33.11 | 81.44 | 83.23 |
| B₃ (%) | 19.27 | 41.93 | — | — |
| A | 19.2957 | 133.9599 | 1094.287 | 1239.651 |
| τ_{avg} (ns) | 1.8693 | 4.6467 | 9.6478 | 9.7944 |
| χ² | 1.4665 | 1.242 | 2.9863 | 2.0797 |

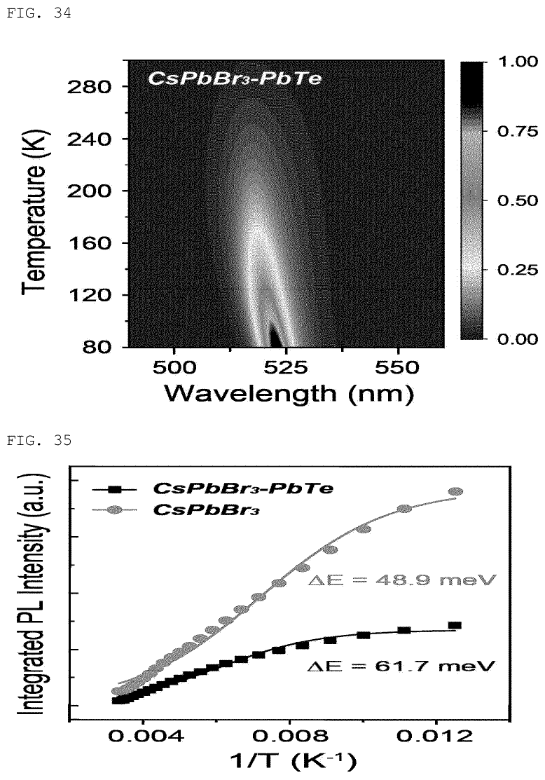

Next, the 2D pseudo-color plot of the temperature-dependent PL spectra was analyzed to determine the depth of exciton localization related to non-radiative decay (FIGS. 34 to 36).

The activation energy (ΔEₜᵣₐₚ) for carrier trapping was calculated by fitting the temperature-dependent PL intensity using I(T)=I₀(1+Ae^{-ΔE}^{ₜᵣₐₚ}^{/k}^{_{B}}^{T})⁻¹. Here, I₀, A, and k_{B} denote the integrated PL intensity at T=0 K, the frequency factor related to the trap state, and the Boltzmann constant, respectively (FIG. 35).

In the case of the pristine CsPbBr₃ NCs, the ΔEₜᵣₐₚ value associated with shallow levels resulting from bromine (Br) vacancies and metallic Pb⁰ was measured to be 48.9 meV. In contrast, the ΔEₜᵣₐₚ value of the CsPbBr₃—PbTe heterostructure NCs increased significantly to about 61.7 meV, suggesting a reduced likelihood of exciton dissociation into free charge carriers at the heterojunction when combining the CsPbBr₃ and PbTe NCs to form a straddling gap (type-I).

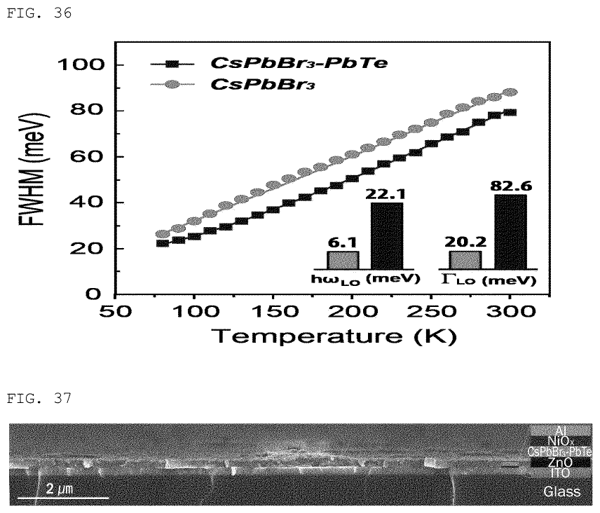

With increasing temperature from 80 to 300 K, a broadening of the PL spectral FWHM was observed in the CsPbBr₃ NCs due to exciton scattering by acoustic and LO phonons. This may be described through the Boson model, expressed by the following equation: (FIG. 36).

Here, Tinh represents the inhomogeneous broadening associated with variations in crystal size and composition, as well as lattice imperfections. Additionally, Γ_{AC}, Γ_{LO}, and ℏω_{LO} denote the exciton-acoustic phonon coupling coefficient, the exciton-LO phonon coupling coefficient, and the LO phonon energy, respectively.

In the pristine CsPbBr₃ NCs, the LO phonon may be depicted as a form of harmonic vibration in which lead (Pb) and bromine (Br) atoms are arranged alternately within the [PbBr₆]⁴⁻ octahedral unit. In contrast, in the CsPbBr₃—PbTe heterostructure NCs, lattice discontinuity at the heterojunction may cause additional exciton scattering. Interestingly, the CsPbBr₃—PbTe heterostructure NCs exhibited slightly increased ℏω_{LO} and Γ_{LO}, compared to the pristine CsPbBr₃ NCs. This confirms that the PbTe NCs grow epitaxially on the CsPbBr₃ NCs, with little lattice mismatch (the insets in FIG. 36).

As a result, in the present disclosure, the CsPbBr₃—PbTe epitaxial heterostructure NCs with coherent interfaces were successfully synthesized, thereby enhancing charge transport and broadening the light absorption range.

By precisely controlling the facet-dependent nucleation and growth of PbTe on the CsPbBr₃ NCs, optimal lattice matching between the {112} facets of orthorhombic CsPbBr₃ and the {111} facets of cubic PbTe was achieved. In particular, the common Pb²⁺ sublattice across the perovskite-chalcogenide interface minimizes lattice strain and promotes robust epitaxial growth of the secondary PbTe phase. The resulting heterostructures exhibit quasi-type I band alignment and nearly complete PL quenching, suggesting efficient interfacial charge transfer.

Furthermore, the light absorption properties, extending from the visible to the IR region, position these CsPbBr₃—PbTe heterostructure NCs as promising candidates for optoelectronic applications, particularly in photovoltaics and photocatalysis.

### Example 2

### (a) Fabrication of CsPbBr₃—PbTe Heterostructure NC-Based Self-Powered Photodetector Device

A perovskite NC-based photodetector was fabricated using a patterned indium tin oxide (ITO) glass substrate.

First, a dense ZnO layer (about 15 to 20 nm) was deposited onto the ITO substrate by thermal atomic layer deposition (ALD) using diethylzinc (DEZ) and deionized water (H₂O), followed by performing spin-coating of CsPbBr₃ and CsPbBr₃—PbTe heterostructure NC solutions at 2,000 rpm for 15 S. Subsequently, a 90 nm-thick nickel oxide (NiOₓ) layer, serving as both a hole transport layer and an electron-blocking layer, was deposited by facing target sputtering. Then, an 80 nm-thick Al electrode was deposited by thermal evaporation.

### (b) Evaluation of Device Characteristics

The photoresponse characteristics of the fabricated photodetector were evaluated using LEDs with wavelengths of 365, 465, and 515 nm. The LEDs were modulated by an optical chopper and connected to a lock-in amplifier for signal detection. The optical power for each LED was controlled using an external power supply device (2400 Source Meter SMU, Keithley Instruments Inc., USA). The power densities were adjusted in the ranges of 0.027 to 0.286 mW/cm² for UV (λ=365 nm), 0.028 to 0.166 mW/cm² for blue (λ=465 nm), and 0.017 to 0.088 mW/cm² for green (λ=515 nm) by varying the operating voltages in the range of 0.5 to 3.0 V. Light intensity was calibrated using a Newport-certified reference silicon photodiode and measured using a power meter. All measurement was performed at room temperature under ambient conditions.

### (c) Analysis of Device Characteristics

To evaluate the optoelectronic performance of the CsPbBr₃—PbTe heterostructure NCs, a photodetector device with a planar structure composed of ITO/ZnO/CsPbBr₃—PbTe/NiOₓ/Al was fabricated (FIG. 37).

The photocurrent responses of a CsPbBr₃ thin film, CsPbBr₃ NCs, and the CsPbBr₃—PbTe heterostructure NCs were measured under monochromatic excitation at three different wavelengths, that is, UV (λ=365 nm), blue (λ=465 nm), and green (λ=515 nm).

All samples exhibited that the photocurrent systematically increased with the respective power densities of the LEDS operated at 0.5 to 3.0 V, and the highest photocurrent was observed at 365 nm. This indicates strong absorption and efficient photogeneration of carriers at 365 nm.

The photodetector produced a stable photocurrent under illumination at an applied bias of 0 V. This shows that the built-in electric field in CsPbBr₃ and CsPbBr₃—PbTe is sufficient to operate the self-powered photodetector.

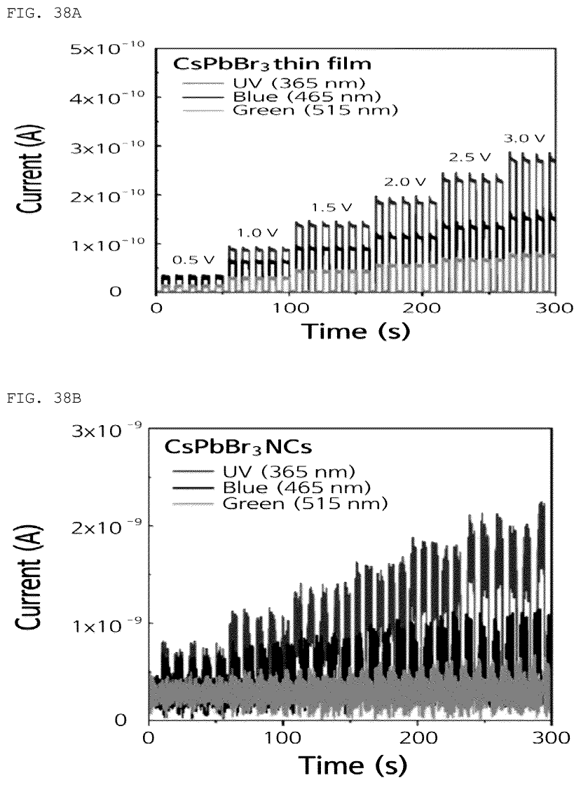

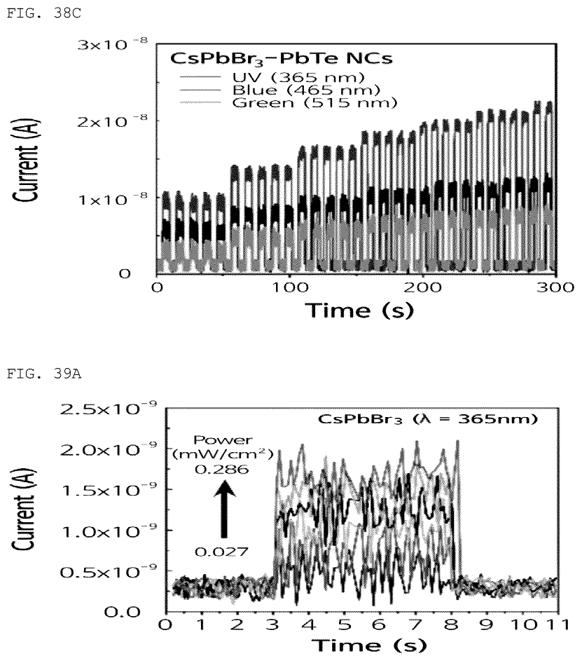

The CsPbBr₃ thin film device exhibited relatively low photocurrent with maximum values of 2.8×10⁻¹⁰ Å (UV), 1.5×10⁻¹⁰ Å (blue), and 0.7×10⁻¹⁰ Å (green). Additionally, the CsPbBr₃ NC-based photodetector exhibited an increase in photocurrent of approximately one order of magnitude under UV and blue illumination. Furthermore, the CsPbBr₃—PbTe heterostructure NC-based device exhibited the highest photocurrents (2.2×10⁻⁸ Å (UV), 1.1×10⁻⁸ Å (blue), and 0.8×10⁻⁸ Å (green)), approximately two orders of magnitude greater than those of the other devices (FIG. 38).

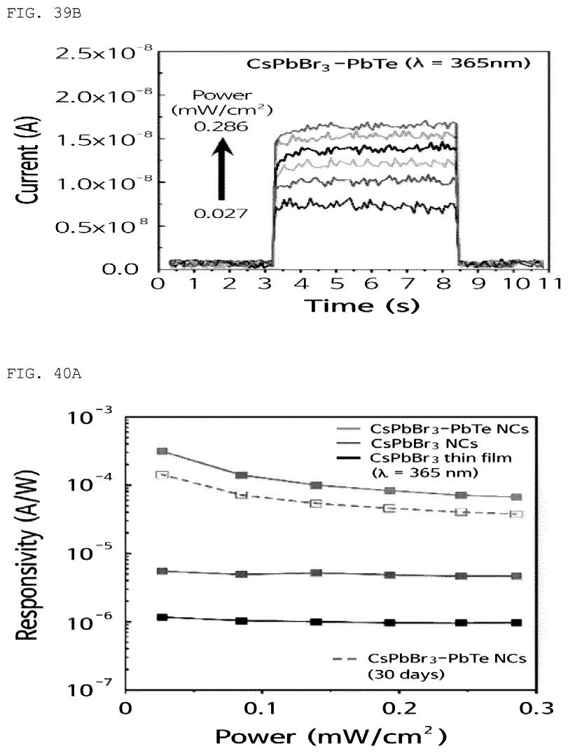

The photocurrent dynamics of the CsPbBr₃—PbTe heterostructure NCs also exhibited a more linear and stable photocurrent response than those of the CsPbBr₃ NCs (FIG. 39).

This indicates that the presence of the PbTe domain on the surface of the CsPbBr₃ NCs in the heterostructure leads to the formation of a type-I band alignment at the CsPbBr₃—PbTe interface, which facilitates faster and more efficient charge extraction, thereby enabling efficient charge separation and transport in the photodetector device.

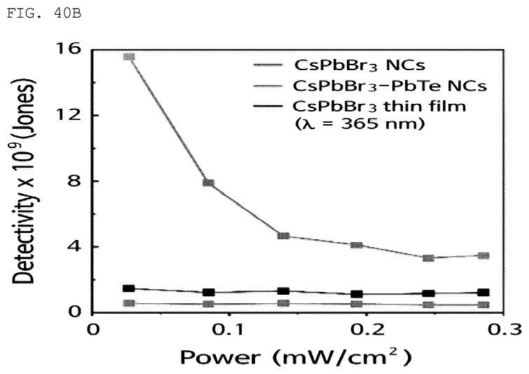

Even the analysis results of the responsivity (R) and specific detectivity (D*) for quantitative evaluation of the photodetector performance reveal the excellent performance of the CsPbBr₃—PbTe heterostructure NC-based photodetector (FIG. 40).

While the present disclosure has been described with reference to the above specific details and limited embodiments, these are provided to help a more general understanding of the present disclosure, and the present disclosure is not limited to the above embodiments. Furthermore, those skilled in the art to which the present disclosure pertains will appreciate that various modifications and variations are possible from the above descriptions.

Therefore, it should be understood that the spirit of the present disclosure is not limited to the embodiments described above, and not only the appended claims but also all equivalents and modifications thereof fall within the scope of the spirit of the present disclosure.

What is claimed is:

1. A metal halide perovskite (MHP)-chalcogenide epitaxial heterostructure nanocrystal (NC) comprising:
a first domain of an MHP satisfying CsPbX₃ (where X is a halide); and
a second domain of a PbTe chalcogenide, the second domain grown on one surface of the first domain,
wherein the first and second domains form an epitaxial junction while achieving lattice matching.

2. The MHP-chalcogenide epitaxial heterostructure NC of claim 1, wherein a (112) plane of the first domain and a (111) plane of the second domain form the epitaxial junction while achieving lattice matching.

3. The MHP-chalcogenide epitaxial heterostructure NC of claim 1, wherein the first and second domains share a common Pb²⁺ sublattice and exhibit structural continuity.

4. The MHP-chalcogenide epitaxial heterostructure NC of claim 1, wherein the first domain has an average size in a range of 5 to 100 nm.

5. The MHP-chalcogenide epitaxial heterostructure NC of claim 4, wherein the first domain has a cubic or polyhedral morphology.

6. The MHP-chalcogenide epitaxial heterostructure NC of claim 1, wherein the second domain has an average size in a range of 1 to 20 nm.

7. The MHP-chalcogenide epitaxial heterostructure NC of claim 6, wherein the second domain has a spherical or polyhedral morphology.

8. The MHP-chalcogenide epitaxial heterostructure NC of claim 1, wherein the MHP-chalcogenide epitaxial heterostructure NC has an average photoluminescence (PL) decay time (τ_{avg}) of 5 ns or less at a temperature of 80 K.

9. The MHP-chalcogenide epitaxial heterostructure NC of claim 1, wherein the MHP-chalcogenide epitaxial heterostructure NC has a PL quantum yield (PLQY) of 5% or less at a temperature of 80 K.

10. A method of preparing an MHP-chalcogenide epitaxial heterostructure NC, the method comprising:
a) preparing a first domain precursor of an MHP satisfying CsPbX₃ (where X is a halide) and a second domain precursor of a PbTe chalcogenide, respectively; and
b) growing a second domain on one surface of a first domain by reacting the first domain precursor with the second domain precursor,
wherein the first and second domains form an epitaxial junction while achieving lattice matching.

11. The method of claim 10, wherein the first domain precursor is prepared by adding and reacting cesium oleate to and with a first reaction solution comprising PbX₂ (where X is a halide), a fatty acid, and a fatty amine.

12. The method of claim 10, wherein the second domain precursor of the PbTe chalcogenide is prepared by reacting a second reaction solution comprising Te powder and trioctylphosphine (TOP).

13. The method of claim 10, wherein the b) growing is performed by reacting a third reaction solution comprising the first domain precursor, the second domain precursor, lead oleate, and 1-dodecanethiol (DDT).

14. An optoelectronic device comprising the MHP-chalcogenide epitaxial heterostructure NC of claim 1.
